(19) United States
(12) Patent Application Publication
(10) Pub. No.: US 2009/0108294 A1
(43) Pub. Date: Apr. 30, 2009

(54) SCALABLE HIGH-K DIELECTRIC GATE STACK

(75) Inventors: Changhwan Choi, Yorktown Heights, NY (US); Takashi Ando, Hartsdale, NY (US); Kisik Choi, Hopewell Junction, NY (US); Vijay Narayanan, New York, NY (US)

Correspondence Address: SCULLY, SCOTT, MURPHY & PRESSER, P.C., 400 GARDEN CITY PLAZA, SUITE 300, GARDEN CITY, NY, 11530, US

(73) Assignees: International Business Machines Corporation, Armonk, NY (US); Advanced Micro Devices, Inc., Sunnyvale, CA (US); Sony Electronics Inc., Park Ridge, NJ (US)

(21) Appl. No.: 11/928,391

(22) Filed: Oct. 30, 2007

(51) Int. Cl. H01L 27/088; H01L 29/78; H01L 21/28; H01L 21/8234

(52) U.S. Cl. 257/190; 257/411; 438/591; 438/275; 257/E27.06; 257/E21.177; 257/E29.255; 257/E21.616

(57) ABSTRACT

A stack comprising a dielectric interface layer, a high-k gate dielectric layer, a group IIA/IIIB element layer is formed in that order on a semiconductor substrate. A metal aluminum nitride layer and, optionally, a semiconductor layer are formed on the stack. The stack is annealed at a raised temperature, e.g., at about 1,000° C. so that the materials in the stack are mixed to form a mixed high-k gate dielectric layer. The mixed high-k gate dielectric layer is doped with a group IIA/IIIB element and aluminum, and has a lower effective oxide thickness (EOT) than a conventional gate stack containing no aluminum. The inventive mixed high-k gate dielectric layer is amenable to EOT scaling due to the absence of a dielectric interface layer, which is caused by scavenging, i.e. consumption of any dielectric interface layer, by the IIA/IIB elements and aluminum.

### FIELD OF THE INVENTION

The present invention generally relates to semiconductor devices, and particularly to semiconductor structures having a scalable high-k dielectric gate stack, and methods of manufacturing the same.

### BACKGROUND OF THE INVENTION

High gate leakage current of silicon oxide and nitrided silicon dioxide as well as depletion effect of polysilicon gate electrodes limits the performance of conventional semiconductor oxide based gate electrodes. High performance devices for an equivalent oxide thickness (EOT) less than 1 nm require high dielectric constant (high-k) gate dielectrics and metal gate electrodes to limit the gate leakage current and provide high on-currents. Materials for high-k gate dielectrics include ZrO₂, HfO₂, other dielectric metal oxides, alloys thereof, and their silicate alloys.

A high-k dielectric material needs to provide good electrical stability, that is, the amount of charge trapped in the high-k dielectric material needs to remain at a low level even after extended operation of a transistor. The high-k dielectric material needs to be scalable, that is, provide an acceptable level of leakage and acceptable levels of electron and hole mobility at a reduced thickness, e.g., less than 1 nm n. High-k dielectric materials satisfying these conditions may be advantageously employed for high performance semiconductor devices.

In general, dual metal gate complementary metal oxide semiconductor (CMOS) integration schemes employ two gate materials, one having a work function near the valence band edge of the semiconductor material in the channel and the other having a work function near the conduction band edge of the same semiconductor material. In CMOS devices having a silicon channel, a conductive material having a work function of about 4.0 eV is necessary for n-type metal oxide semiconductor field effect transistors (NMOSFETs, or “NFETs”) and another conductive material having a work function of about 5.0 eV is necessary for p-type metal oxide semiconductor field effect transistors (PMOSFETs, or “PFETs”). In conventional CMOS devices employing polysilicon gate materials, a heavily p-doped polysilicon gate and a heavily n-doped polysilicon gate are employed to address the needs. In CMOS devices employing high-k gate dielectric materials, two types of gate stacks comprising suitable materials satisfying the work function requirements are needed for the PFETs and for the NFETS, in which the gate stack for the PFETs provides a flat band voltage closer to the valence band edge of the material of the channel of the PFETs, and the gate stack for the NFETs provides a flat band voltage closer to the conduction band edge of the material of the channel of the NFETs. In other words, threshold voltages need to be optimized differently between the PFETs and the NFETs.

Such independent adjustment of threshold voltages may be effected by introducing different threshold voltage adjustment dielectric layers between the PFETs and the NFETs above a common high-k gate dielectric layer. An adverse effect of such threshold voltage adjustment dielectric layers is an increase of the EOT of the high-k gate dielectric stacks due to the physical thickness of the threshold voltage adjustment dielectric layers.

In view of the above, there exists a need for high-k gate dielectric stacks that allow scaling of the thickness of the gate dielectric stacks, while providing mechanisms for independently optimizing the threshold voltages of PFETs and NFETs, and methods of manufacturing the same.

Further, there exists a need for CMOS devices that provide scaling of both PFETs and NFETs, while at the same time enabling optimization of threshold voltages for both types of transistors, and methods of manufacturing the same.

### SUMMARY OF THE INVENTION

The present invention addresses the needs described above by providing a high-k gate dielectric stack structure providing an enhanced scalability than prior art structures and providing an optimized threshold voltage for a transistor, and methods of manufacturing the same.

In the present invention, a stack comprising a dielectric interface layer, a high-k gate dielectric layer, a group IIA/IIIB element layer is formed in that order on a semiconductor substrate. A metal aluminum nitride layer and, optionally, a semiconductor layer are formed on the stack. The stack is annealed at a raised temperature, e.g., at about 1,000° C. so that the materials in the stack are mixed to form a mixed high-k gate dielectric layer. The mixed high-k gate dielectric layer is doped with a group IIA/IIIB element and aluminum, and has a lower effective oxide thickness (EOT) than a comparable conventional stack formed without an aluminum nitride layer, which renders the mixed high-k gate dielectric layer amenable to scaling.

In the inventive structure containing the mixed high-k gate dielectric layer, no interfacial dielectric layer is present between the substrate and the mixed high-k gate dielectric layer, enabling scaling of the gate dielectric. While group IIA elements and group IIIB elements have been known to shift the flat-band voltage close to a conduction band edge, addition of aluminum into the composition of the mixed high-k gate dielectric layer provides mid-gap workfunction characteristics. During the research leading to the present invention, it has been discovered that even the presence of IIA and IIIB elements does not make flat-band voltage shift toward the conduction band edge when aluminum is present in sufficient quantity in the mixed high-k gate dielectric layer.

NFETs and/or PFETs employing the mixed high-k gate dielectric layer of the present invention may be formed. Threshold voltages for the NFETs and the PFETs may be adjusted by optimizing the composition of the group IIA/IIIB element layer and the composition of the metal aluminum nitride layer, especially the aluminum content thereof and optionally, by providing another layer containing a group IIA/IIIB element between the dielectric interface layer and the high-k gate dielectric layer.

According to an aspect of the present invention, a semiconductor structure is provided, which includes:

a high dielectric constant (high-k) material layer vertically abutting a top surface of a semiconductor substrate and comprising a dielectric material having a dielectric constant greater than 8.0 and doped with aluminum and a group IIA element or a group IIIB element; and

a metallic layer located directly on the high-k material layer.

In one embodiment, the high-k material layer is homogeneous and vertically graded in composition with a concentration gradient in aluminum or one of the group IIA elements and the group IIIB elements.

In another embodiment, the high-k material layer comprises one of HfMₚAl_{q}O₂₊ᵣ, ZrMₚAl_{q}O₂₊ᵣ, La₂MₚAl_{q}O₃₊ᵣ, Al₂MₚO₃₊ᵣ, TiMₚAl_{q}O₂₊ᵣ, SrTiMₚAl_{q}O₃₊ᵣ, LaAl MₚO₃₊ᵣ, Y₂MₚAl_{q}O₃₊ᵣ, HfMₚAl_{q}OₓN_{y}, ZrMₚAl_{q}OₓN_{y}, La₂MₚAl_{q}OₓN_{y}, Al₂MₚOₓN_{y}, TiMₚAl_{q}OₓN_{y}, SrTiMₚAl_{q}OₓN_{y}, LaAlMₚOₓN_{y}, Y₂MₚAl_{q}OₓN_{y}, a silicate thereof, and an alloy thereof, wherein M is selected from Be, Mg, Ca, Sr, Ba, Ra, Sc, Y, La, Ce, Pr, Nd, Pm, Sm, Eu, Gd, Tb, Dy, Ho, Er, Tm, Yb, and Lu, and wherein each value of p is independently from 0 and to about 0.5, and each value of q is independently from 0 and to about 0.5, and each value of r is independently from about 0 and to about 1, and each value of x is independently from about 0.5 to about 3, and each value of y is independently from 0 to about 2.

In even another embodiment, the metallic layer comprises a metal aluminum nitride containing aluminum, nitrogen, and a metal other than aluminum.

In yet another embodiment, the semiconductor structure further comprises a semiconductor layer abutting the metal aluminum nitride layer.

In still another embodiment, the metallic layer comprises a silicon valence band edge metal or a silicon conduction band edge metal, wherein the silicon valence band edge metal is one of Pt, Rh, ft, Re and Ru, and wherein the silicon conduction band edge metal is one of Hf, Ti, and Zr.

In still yet another embodiment, the semiconductor structure further comprises a conductive capping layer abutting the metallic layer, wherein the conductive capping layer comprises doped polysilicon or one of TaAlN, TiN, ZrN, HfN, VN, NbN, TaN, WN, TiAlN, TaCN, W, Ta, Ti, other conductive refractory metal nitrides, and an alloy thereof.

According to another aspect of the present invention, another semiconductor structure is provided, which includes:

a first high dielectric constant high-k) material layer vertically abutting a top surface of a semiconductor substrate and comprising a first dielectric material having a dielectric constant greater than 8.0 and doped with aluminum and a group IIA element or a group IIIB element;

a first metallic layer located directly on the first high-k material layer;

a second high dielectric constant (high-k) material layer located on the semiconductor substrate, disjoined from the first high-k material layer, and comprising a second dielectric material having a dielectric constant greater than 8.0 and doped with aluminum and a group IIA element or a group IIIB element, wherein the first dielectric material and the second dielectric material have different compositions; and

a second metallic layer located directly on the second high-k material layer;

In one embodiment, each of the first high-k material layer and the second high-k material layer is homogeneous.

In another embodiment, each of the first high-k material layer and the second high-k material layer comprises one of HfMₚAl_{q}O₂₊ᵣ, ZrMₚAl_{q}O₂₊ᵣ, La₂MₚAl_{q}O₃₊ᵣ, Al₂MₚO₃₊ᵣ, TiMₚAl_{q}O₂₊ᵣ, SrTiMₚAl_{q}O₃₊ᵣ, LaAlMₚO₃₊ᵣ, Y₂MₚAl_{q}O₃₊ᵣ, HfMₚAl_{q}OₓN_{y}, ZrMₚAl_{q}OₓN_{y}, La₂MₚAl_{q}OₓN_{y}, Al₂MₚOₓN_{y}, TiMₚAl_{q}OₓN_{y}, SrTiMₚAl_{q}OₓN_{y}, LaAlMₚOₓN_{y}, Y₂MₚAl_{q}OₓN_{y}, a silicate thereof, and an alloy thereof, wherein M is selected from Be, Mg, Ca, Sr, Ba, Ra, Sc, Y, La, Ce, Pr, Nd, Pm, Sm, Eu, Gd, Tb, Dy, Ho, Er, Tm, Yb, and Lu, and wherein each value of p is independently from 0 and to about 0.5, and each value of q is independently from 0 and to about 0.5, and each value of r is independently from about 0 and to about 1, and each value of x is independently from about 0.5 to about 3, and each value of y is independently from 0 to about 2.

In even another embodiment, the first metallic layer and the second metallic layer have the same composition and comprise a metal aluminum nitride containing aluminum, nitrogen, and a metal other than aluminum.

In yet another embodiment, the semiconductor structure further comprises a first doped semiconductor layer and a second doped semiconductor layer, wherein the first doped semiconductor layer abuts the first metal layer and the second doped semiconductor layer abuts the second metal layer.

In still another embodiment, the first metallic layer comprises a silicon valence band edge metal and the second metallic layer comprises a silicon conduction band edge metal, wherein the silicon valence band edge metal is one of Pt, Rh, ft, Re and Ru, and wherein the silicon conduction band edge metal is one of Hf. Ti, and Zr.

In still yet another embodiment, the semiconductor structure further comprises a silicon germanium alloy layer vertically abutting the semiconductor substrate and the second high-k material layer and disjoined from the first high-k material layer.

In a further embodiment, the semiconductor structure further comprises:

a dielectric nitride spacer laterally abutting the first high-k material layer and the first metallic layer;

a first dielectric oxide spacer laterally abutting the dielectric nitride spacer; and

a second dielectric oxide spacer laterally abutting the second high-k material layer and the second metallic layer, wherein the first dielectric oxide spacer and the second dielectric oxide spacer have the same composition.

In an even further embodiment, the second high-k material layer has a higher atomic percentage of oxygen than the first high-k material layer.

In a yet further embodiment, the semiconductor structure further comprises:

a first dielectric spacer laterally abutting the first high-k material layer and the first metallic layer; and

a second dielectric spacer laterally abutting the second high-k material layer and the second metallic layer, wherein the first dielectric spacer and the second dielectric spacer have a different composition.

In a still further embodiment, the second high-k material layer has a higher atomic percentage of oxygen than the first high-k material layer.

In a still yet further embodiment, the semiconductor structure further comprises a third dielectric spacer located on the first dielectric spacer, wherein the second dielectric spacer and the third dielectric spacer have the same composition.

According to yet another aspect of the present invention, yet another semiconductor structure is provided, which includes:

a dielectric interface layer vertically abutting a top surface of a semiconductor substrate, wherein the dielectric interface layer comprises a semiconductor oxide, a semiconductor oxynitride, or a semiconductor nitride;

a high dielectric constant (high-k) material layer vertically abutting the dielectric interface layer, wherein the high-k material layer has a dielectric constant greater than 8.0; and

a group IIA/IIIB element layer vertically abutting the high-k material layer and comprising a group IIA element or a group IIIB element.

In one embodiment, the high-k material layer comprises one of HfO₂, ZrO₂, La₂O₃, Al₂O₃, TiO₂, SrTiO₃, LaAlO₃, Y₂O₃, HfOₓN_{y}, ZrOₓN_{y}, La₂OₓN_{y}, Al₂OₓN_{y}, TiOₓN_{y}, SrTiOₓN_{y}, LaAlOₓN_{y}, Y₂OₓN_{y}, a silicate thereof, and an alloy thereof, wherein each value of x is independently from about 0.5 to about 3 and each value of y is independently from 0 to about 2.

In another embodiment, the group IIA/IIIB element layer comprises one of Be, Mg, Ca, Sr, Ba, Ra, Sc, Y, La, Ce, Pr, Nd, Pm, Sm, Eu, Gd, Tb, Dy, Ho, Er, Tm, Yb, and Lu.

In even another embodiment, the semiconductor structure further includes a metal aluminum nitride layer vertically abutting the group IIA/IIIB element layer and comprising aluminum, nitrogen, and a metal other than aluminum.

In yet another embodiment, the semiconductor structure further comprises a semiconductor layer abutting the metal aluminum nitride layer.

In a still further embodiment, the semiconductor layer comprises polysilicon.

In a still yet further embodiment, the dielectric interface layer has a thickness from abut 0.1 nm to about 0.8 nm, the high-k material layer has a thickness from about 1.2 nm to about 3.0 nm, and the group IIA/IIIB element layer has a thickness from about 0.1 nm to about 0.5 nm.

According to even another aspect of the present invention, a method of manufacturing a semiconductor structure is provided which comprises:

forming a stack comprising, from bottom to top, a dielectric interface layer, a high dielectric constant (high-k) material layer, and a group IIA/IIIB element layer in that order directly on a semiconductor substrate, wherein the dielectric interface layer comprises a semiconductor oxide, a semiconductor oxynitride, or a semiconductor nitride, wherein the high-k material layer has a dielectric constant greater than 8.0, and wherein the group IIA/IIIB element layer comprises one of the group IIA elements and the group IIIB elements;

forming a metal aluminum nitride layer comprising aluminum, nitrogen, and a metal other than aluminum directly on the stack; and

annealing the stack to form a mixed high-k material layer abutting the semiconductor substrate and the metal aluminum nitride layer, wherein the mixed high-k material layer has a dielectric constant greater than 8.0 and comprises aluminum and the one of the group IIA elements and the group IIIB elements.

In one embodiment, the method further comprises forming a semiconductor layer directly on the metal aluminum nitride layer.

In another embodiment, the high-k material layer comprises one of HfO₂, ZrO₂, La₂O₃, Al₂O₃, TiO₂, SrTiO₃, LaAlO₃, Y₂O₃, HfOₓN_{y}, ZrOₓN_{y}, La₂OₓN_{y}, Al₂OₓN_{y}, TiOₓN_{y}, SrTiOₓN_{y}, LaAlOₓN_{y}, Y₂OₓN_{y}, a silicate thereof, and an alloy thereof, wherein each value of x is independently from about 0.5 to about 3 and each value of y is independently from 0 to about 2.

In even another embodiment, the group IIA/IIIB element layer comprises one of Be, Mg, Ca, Sr, Ba, Ra, Sc, Y, La, Ce, Pr, Nd, Pm, Sm, Eu, Gd, Tb, Dy, Ho, Er, Tm, Yb, and Lu.

In yet another embodiment, the method further comprises patterning the mixed high-k material layer and the metal aluminum nitride layer to form a gate conductor stack.

In still another embodiment, the method further comprises:

forming a dielectric layer on the gate conductor stack;

planarizing the dielectric layer to expose the gate conductor stack;

removing the metal aluminum nitride layer from the gate conductor stack; and

forming a metallic layer comprising a silicon valence band edge metal or a silicon conduction band edge metal, wherein the silicon valence band edge metal is one of Pt, Rh, Ir, Re and Ru, and wherein the silicon conduction band edge metal is one of Hf Ti, and Zr.

According to still another aspect of the present invention, another method of forming a semiconductor structure is provided, which comprises:

forming a first stack comprising, from bottom to top, a dielectric interface layer, a metal oxide layer, a high dielectric constant (high-k) material layer, and a group IIA/IIIB element layer directly on a first portion of a semiconductor substrate, wherein the dielectric interface layer comprises a semiconductor oxide, a semiconductor oxynitride, or a semiconductor nitride, wherein the high-k material layer has a dielectric constant greater than 8.0, and wherein the a group IIA/IIIB element layer comprises one of the group IIA elements and the group IIIB elements;

forming a second stack comprising, from bottom to top, the dielectric interface layer, the high-k material layer, and the group IIA/IIB element layer directly on a second portion of the semiconductor substrate;

forming a metal aluminum nitride layer comprising aluminum, nitrogen, and a metal other than aluminum directly on the first stack and the second stack; and

annealing the first stack and the second stack to form a first mixed high-k material layer and a second mixed high-k material layer respectively, wherein each of the first mixed high-k material layer and the second mixed high-k material layer abuts the semiconductor substrate and the metal aluminum nitride layer, has a dielectric constant greater than 8.0, and comprises aluminum and the one of the group IIA elements and the group IIIB elements, and wherein the first mixed high-k material layer and the second mixed high-k material layer have different compositions.

In one embodiment, the high-k material layer comprises one of HfO₂, ZrO₂, La₂O₃, Al₂O₃, TiO₂, SrTiO₃, LaAlO₃, Y₂O₃, HfOₓN_{y}, ZrOₓN, La₂OₓN_{y}, Al₂OₓN_{y}, TiOₓN_{y}, SrTiOₓN_{y}, LaAlOₓN_{y}, Y₂OₓN_{y}, a silicate thereof, and an alloy thereof, wherein each value of x is independently from about 0.5 to about 3 and each value of y is independently from 0 to about 2, and wherein each of the first mixed high-k material layer and the second mixed high-k material layer comprises one of HfMₚAl_{q}O₂₊ᵣ, ZrMₚAl_{q}O₂₊ᵣ, La₂MₚAl_{q}O₃₊ᵣ, Al₂MₚO₃₊ᵣ, TiMₚAl_{q}O₂₊ᵣ, SrTiMₚAl_{q}O₃₊ᵣ, LaAlMₚO₃₊ᵣ, Y₂MₚAl_{q}O₃₊ᵣ, HfMₚAl_{q}OₓN_{y}, ZrMₚAl_{q}OₓN_{y}, La₂MₚAl_{q}OₓN_{y}, Al₂MₚOₓN_{y}, TiMₚAl_{q}OₓN_{y}, SrTiMₚAl_{q}OₓN_{y}, LaAlMₚOₓN_{y}, Y₂MₚAl_{q}OₓN_{y}, a silicate thereof, and an alloy thereof, wherein M is selected from Be, Mg, Ca, Sr, Ba, Ra, Sc, Y, La, Ce, Pr, Nd, Pm, Sm, Eu, Gd, Tb, Dy, Ho, Er, Tm, Yb, and Lu, and wherein each value of p is independently from 0 and to about 0.5, and each value of q is independently from 0 and to about 0.5, and each value of r is independently from about 0 and to about 1, and each value of x is independently from about 0.5 to about 3, and each value of y is independently from 0 to about 2.

In another embodiment, the group IIA/IIIB element layer comprises one of Be, Mg, Ca, Sr, Ba, Ra, Sc, Y, La, Ce, Pr, Nd, Pm, Sm, Eu, Gd, Tb, Dy, Ho, Er, Tm, Yb, and Lu.

We have to address deposition methods for these films such as evaporation, PVD, CVD and ALD.

In even another embodiment, the method further comprises forming a silicon germanium alloy layer directly on a portion of the semiconductor substrate, wherein the second high-k material layer is formed directly on the portion of the semiconductor substrate, wherein the first high-k material layer is formed directly on the semiconductor substrate, and wherein the semiconductor substrate comprises silicon.

In yet another embodiment, the method further comprises:

forming a dielectric nitride spacer directly on the first mixed high-k material layer and the first metallic layer;

forming a first dielectric oxide spacer directly on the dielectric nitride spacer; and

forming a second dielectric oxide spacer directly on the second high-k material layer and the second metallic layer, wherein the first dielectric oxide spacer and the second dielectric oxide spacer have the same composition.

In still another embodiment, the method further comprises:

forming a first dielectric spacer on the semiconductor substrate, wherein a first portion of the first dielectric layer laterally abuts the first mixed high-k material layer and a second portion of the first dielectric layer laterally abuts the second mixed high-k material layer;

removing the second portion to expose sidewalls of the second mixed high-k material layer, while preserving the first portion; and

oxidizing the second mixed high-k material layer, while preventing diffusion of oxygen into the first mixed high-k material layer.

### BRIEF DESCRIPTION OF THE DRAWINGS

FIG. 1 is a vertical cross-sectional view of a first exemplary semiconductor structure prior to an anneal according to a first embodiment of the present invention.

FIG. 2 is a vertical cross-sectional view of the first exemplary semiconductor structure after the anneal according to the first embodiment of the present invention.

FIG. 3 is a graph showing capacitance densities for three different gate stacks including the inventive gate stack according to the first embodiment of the present invention.

FIGS. 4-6 are sequential vertical cross-sectional views of a second exemplary semiconductor structure according to a second embodiment of the present invention.

FIGS. 7-11 are sequential vertical cross-sectional views of a third exemplary semiconductor structure according to a third embodiment of the present invention.

FIGS. 12-16 are sequential vertical cross-sectional views of a fourth exemplary semiconductor structure according to a fourth embodiment of the present invention.

FIG. 17 is a vertical cross-sectional view of a fifth exemplary semiconductor structure according to a fifth embodiment of the present invention.

FIG. 18 is a vertical cross-sectional view of a sixth exemplary semiconductor structure according to a sixth embodiment of the present invention.

FIGS. 19-21 are sequential vertical cross-sectional views of a seventh exemplary semiconductor structure according to a seventh embodiment of the present invention.

### DETAILED DESCRIPTION OF THE INVENTION

As stated above, the present invention relates to semiconductor structures having a scalable high-k dielectric gate stack, and methods of manufacturing the same, which are now described in detail with accompanying figures. It is noted that like and corresponding elements mentioned herein and illustrated in the drawings are referred to by like reference numerals. It is also noted that proportions of various elements in the accompanying figures are not drawn to scale to enable clear illustration of elements having smaller dimensions relative to other elements having larger dimensions.

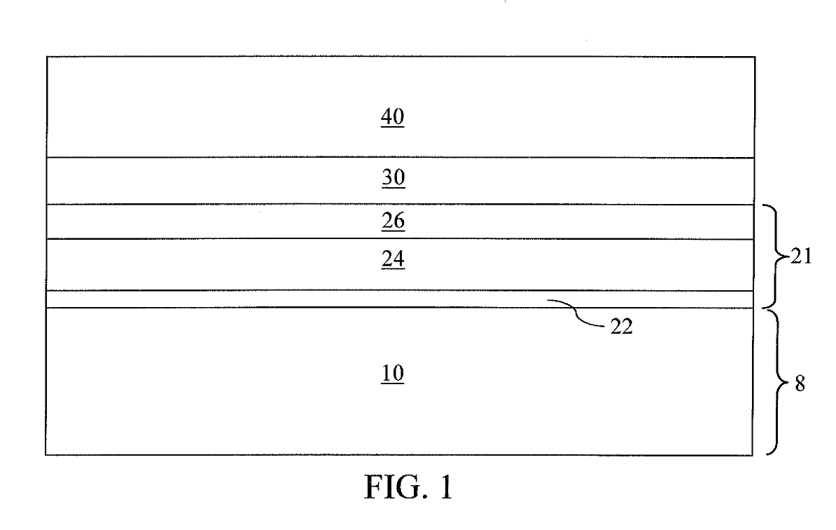

Referring to FIG. 1, a first exemplary semiconductor structure according to a first embodiment of the present invention comprises a semiconductor substrate 8 containing a semiconductor region 10 comprising a semiconductor material, which may be selected from, but is not limited to, silicon, germanium, silicon-germanium alloy, silicon carbon alloy, silicon-germanium-carbon alloy, gallium arsenide, indium arsenide, indium phosphide, III-V compound semiconductor materials, II-VI compound semiconductor materials, organic semiconductor materials, and other compound semiconductor materials. Preferably, the semiconductor region 10 is single crystalline, i.e., have the same set of crystallographic orientations, or “epitaxial.”

The semiconductor substrate 8 may be a bulk substrate, a semiconductor-on-insulator (SOI) substrate, or a hybrid substrate having a bulk portion and an SOI portion. While the first embodiment is described with a bulk substrate, embodiments employing an SOI substrate or a hybrid substrate are explicitly contemplated herein.

The semiconductor region 10 may include at least one doped region, each having a p-type doping or an n-type doping. For clarity, the at least one doped region is not specifically shown in the drawing of the present application. Each of the at least one doped region is known as a “well” and may be formed utilizing conventional ion implantation processes. The semiconductor region 10 may also contain at least one shallow trench isolation structure (no shown) and/or a deep trench capacitor (not shown).

A dielectric interface layer 22 is formed directly on the semiconductor region 10. The dielectric interface layer 22 may comprise a semiconductor oxide, a semiconductor oxynitride, or a semiconductor nitride. In case the semiconductor region 10 comprises silicon, the dielectric interface layer 22 may comprise silicon oxide, silicon oxynitride, or silicon nitride. The thickness of the dielectric interface layer 22 may be from about 0.1 nm to about 0.8 nm, although lesser and greater thicknesses are also contemplated herein.

For example, the dielectric interface layer 22 may be a “chemical oxide,” which is formed by treatment of a top surface of the semiconductor region 10 with a chemical. The process step for this wet chemical oxidation typically includes treating a cleaned semiconductor surface (such as a semiconductor surface treated with hydrofluoric acid) with a mixture of ammonium hydroxide, hydrogen peroxide and water (in a 1:1:5 ratio) at 65 Cc. Alternately, the chemical oxide layer can also be formed by treating the HF-last semiconductor surface in ozonated aqueous solutions, with the ozone concentration usually varying from, but not limited to: 2 parts per million (ppm) to 40 ppm.

A high dielectric constant (high-k) material layer 24 is formed directly on the dielectric interface layer 22 by methods well known in the art including, for example, chemical vapor deposition (CVD), physical vapor deposition (PVD), molecular beam deposition (MBD), pulsed laser deposition (PLD), liquid source misted chemical deposition (LSMCD), atomic layer deposition (ALD), etc. The high-k material layer 24 comprises a dielectric metal oxide having a dielectric constant that is greater than the dielectric constant of silicon oxide of 3.9. Preferably, the high-k material layer 24 has a dielectric constant greater than 8.0. The dielectric metal oxide is a high-k material containing a metal and oxygen, and is known in the art as high-k gate dielectric materials. Exemplary high-k dielectric material include HfO₂, ZrO₂, La₂O₃, Al₂O₃, TiO₂, SrTiO₃, LaAlO₃, Y₂O₃, HfOₓN_{y}, ZrOₓN_{y}, La₂OₓN_{y}, Al₂OₓN_{y}, TiOₓN_{y}, SrTiOₓN_{y}, LaAlOₓN_{y}, Y₂OₓN_{y}, a silicate thereof, and an alloy thereof. Each value of x is independently from about 0.5 to about 3 and each value of y is independently from 0 to about 2. The thickness of the high-k material layer 24 may be from about 0.9 nm to about 6 nm, and preferably from about 1.2 nm to about 3 nm. The high-k material layer 24 may have an effective oxide thickness on the order of or less than 1 nm.

A group IIA/IIIB element layer 26 is thereafter formed directly on the high-k material layer 24 by methods well known in the art including, for example, CVD, PVD, MBD, PLD, LSMCD, ALD, etc. The group IIA/IIIB element layer 26 comprises one of the group IIA elements and the group IIIB elements. Specifically, the group IIA/IIIB element layer 26 may comprise one of Be, Mg, Ca, Sr, Ba, Ra, Sc, Y, La, Ce, Pr, Nd, Pm, Sm, Eu, Gd, Tb, Dy, Ho, Er, Tm, Yb, and Lu. The thickness of the group IIA/IIIB element layer 26 may be from about 0.1 nm to about 0.8 nm, although lesser and greater thicknesses are also explicitly contemplated. Due to the propensity of the group IIA elements and the group IIIB elements, the group IIA/IIIB element layer 26 contains an oxidized compound of one or more of the group IIA elements and the group IIIB elements, i.e., an oxide of one or more of the group IIA elements and the group IIIB elements.

The dielectric interface layer 22, the high-k material layer 24, and the group IIA/IIIB element layer 26 are collectively referred to as a dielectric stack 21.

A metal aluminum nitride layer 30 is formed directly on the group IIA/IIIB element layer 26 by deposition methods known in the art. The metal aluminum nitride layer 30 comprises aluminum, nitrogen, and a metal other than aluminum. The metal other than aluminum may be a transition metal, a rare earth metal, Be, Mg, Ga, In, Tl, Sn, Pb, or Bi. A plurality of metallic elements other than aluminum may be present in the metal aluminum nitride layer 30. Preferably, the metal other than aluminum may be one of Co, Ta, and Be. Preferably, the metal other than aluminum is more electronegative, for example, in the Pauling scale, than the metallic elements contained in the high-k material layer 24. For example, if the high-k material layer 24 comprises HfO₂, ZrO₂, or La₂O₃, the metal other than aluminum has an electronegativity value greater than the electronegativity values for Hf, Zr, or La, which is 1.3, 1.33, or 1.1, respectively. In this case, any of Co, Ta, and Be, which have electronegativity values of 1.88, 1.5, and 1.57, respectively, satisfy the condition of having a greater electronegativity than the electronegativity of the metal contained in the high-k material layer 24. The thickness of the metal aluminum nitride layer 30 may be from about 0.1 nm to about 100 nm, and typically from about 1 nm to about 10 nm, although lesser and greater thicknesses are also explicitly contemplated herein.

A semiconductor layer 40 is formed directly on the metal aluminum nitride layer 30 by deposition methods well known in the art. The semiconductor layer 40 may comprise a polycrystalline or amorphous semiconductor material, which includes at least one of silicon, germanium, silicon-germanium alloy, silicon carbon alloy, silicon-germanium-carbon alloy, gallium arsenide, indium arsenide, indium phosphide, III-V compound semiconductor materials, II-VI compound semiconductor materials, organic semiconductor materials, and other compound semiconductor materials. The semiconductor layer 40 may be deposited with in-situ doping as a doped semiconductor material layer, or may be deposited as an undoped semiconductor material layer and subsequently doped by ion implantation. The thickness of the semiconductor layer 40 may be from about 10 nm to about 120 nm, although lesser and greater thicknesses are also explicitly contemplated herein.

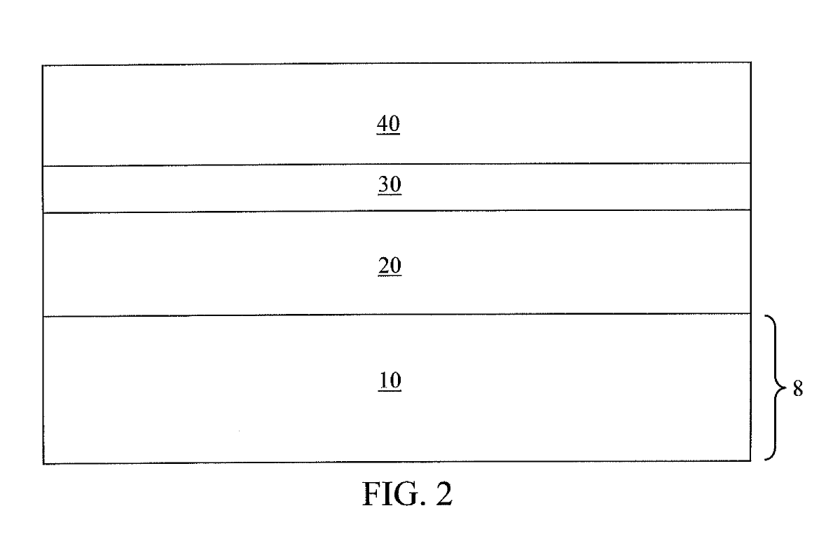

Referring to FIG. 2, the first exemplary semiconductor structure is annealed at an elevated temperature to induce interdiffusion of materials in the dielectric stack 21, i.e., within the collective set of the dielectric interface layer 22, the high-k material layer 24, and the group IIA/IIB element layer 26. In addition, some aluminum atoms diffuse out of the metal aluminum nitride layer 30 into the dielectric stack 21. The dielectric stack 21 is mixed by diffusion of the materials of the dielectric interface layer 22, the high-k material layer 24, the group IIA/IIIB element layer 26 and the outdiffused aluminum to form a mixed high-k material layer 20. The mixing herein includes complete homogenization in which the mixed high-k material layer 20 becomes completely homogeneous, as well as substantial homogenization in which the mixed high-k material layer 20 becomes substantially homogeneous. Alternately, the mixed high-k material layer 20 may be vertically graded in composition with a concentration gradient in aluminum or one of the group IIA elements and the group IIIB elements. Thus, the mixed high-k material layer 20 may be a homogenized high-k material layer or a vertically graded high-k material layer.

The elevated temperature during the anneal may be from about 800° C. to about 1,200° C., and typically from about 900° C. to about 1,100° C. The duration of the anneal at the elevated temperature may be from about 1 second to about 30 minutes, and typically from about 1 second to about 3 minutes depending on the elevated temperature.

The mixed high-k material layer 20 comprises the material of the high-k material layer 24, aluminum, and the material of the IIA/IIB element layer 26, which is one of the group IIA elements and the group IIIB elements. Thus, the mixed high-k material layer 20 may comprise one of HfMₚAl_{q}O₂₊ᵣ, ZrMₚAl_{q}O₂₊ᵣ, La₂MₚAl_{q}O₃₊ᵣ, Al₂MₚO₃₊ᵣ, TiMₚAl_{q}O₂₊ᵣ, SrTiMₚAl_{q}O₃₊ᵣ, LaAlMₚO₃₊ᵣ, Y₂MₚAl_{q}O₃₊ᵣ, HfMₚAl_{q}OₓN_{y}, ZrMₚAl_{q}OₓN_{y}, La₂MₚAl_{q}OₓN_{y}, Al₂MₚOₓN_{y}, TiMₚAl_{q}OₓN_{y}, SrTiMₚAl_{q}OₓN_{y}, LaAlMₚOₓN_{y}, Y₂MₚAl_{q}OₓN_{y}, a silicate thereof and an alloy thereof. M is selected from the group IIA elements and the group IIIB elements, i.e., Be, Mg, Ca, Sr, Ba, Ra, Sc, Y. La, Ce, Pr, Nd, Pm, Sm, Eu, Gd, Tb, Dy, Ho, Er, Tm, Yb, and Lu. Each value of p is independently from 0 and to about 0.5, and each value of q is independently from 0 and to about 0.5, and each value of r is independently from about 0 and to about 1. Each value of x is independently from about 0.5 to about 3, and each value of y is independently from 0 to about 2.

The first semiconductor structure after the anneal thus comprises the semiconductor substrate 8 containing the semiconductor region 10, the mixed high-k material layer 20 located directly thereupon, the metal aluminum nitride layer 30, and the semiconductor layer 40.

The mixed high-k material layer 20 has a high dielectric constant greater than 8.0. Thus, unlike prior art structures in which a dielectric interface layer having a dielectric constant less than 8.0 and effectively reduces the capacitance density, or an effective dielectric constant, of a dielectric stack, the present invention provides a structure in which the mixed high-k material layer 20, which has a dielectric constant greater than 8.0 within the entirety thereof, directly contacts the semiconductor substrate 8. Such direct contact provides the advantage of higher capacitance density and higher effective dielectric constant, and also enables scaling of a gate dielectric, which consists of the mixed high-k material layer 20, and does not contain an interfacial dielectric layer having a dielectric constant less than 8.0 according to the present invention.

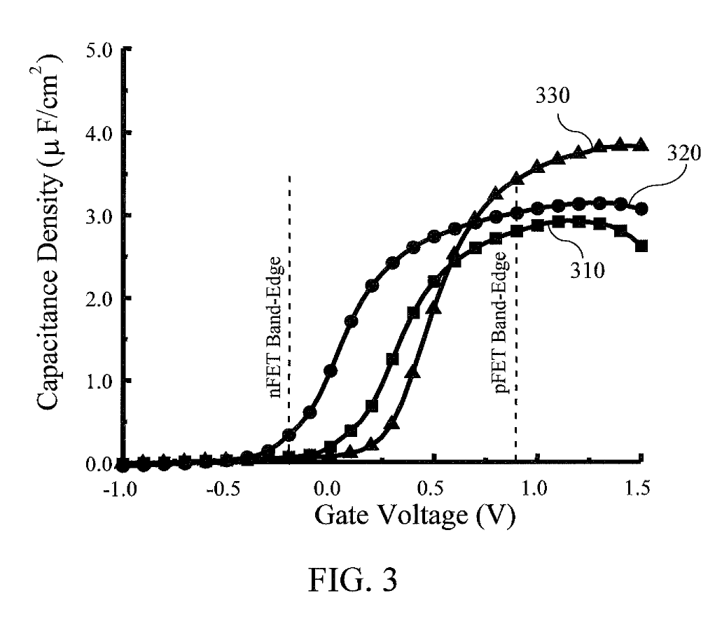

FIG. 3 shows a graph in which capacitance densities are plotted for p-type field effect transistors having three different gate stacks having the same equivalent oxide thickness. A first capacitance density curve 310 is for a first gate stack consisting of a dielectric interface layer consisting of silicon oxide having a thickness of 0.6 nm, a high-k material layer consisting of HfO₂ and having a thickness of 2.2 nm, a metallic layer comprising TiN and having a thickness of about 10 nm, and a semiconductor layer comprising polysilicon and having a thickness of about 100 nm. A second capacitance density curve 320 is for a second gate structure consisting of a dielectric interface layer consisting of silicon oxide having a thickness of 0.6 nm, a high-k material layer consisting of HfO₂ and having a thickness of 2.2 nm, a group IIA/IIB element layer consisting of La₂O₃ and having a thickness of 0.4 nm, a metallic layer comprising TiN and having a thickness of about 10 nm, and a semiconductor layer comprising polysilicon and having a thickness of about 100 nm. The dielectric interface layer, the high-k material layer, and the group II/IIB element layer are distinct, i.e., not mixed by an anneal in the second gate structure. The third capacitance density curve 330 is for a third gate structure employing the first exemplary semiconductor structure according to the first embodiment of the present invention. Particularly, the third gate structure comprises a mixed high-k material layer, a metallic layer comprising TiN and having a thickness of about 10 nm, and a semiconductor layer comprising polysilicon and having a thickness of about 100 nm. The mixed high-k material layer is formed by annealing a stack of a dielectric interface layer consisting of silicon oxide having a thickness of 0.6 nm, a high-k material layer consisting of HfO₂ and having a thickness of 2.2 nm, a group IIA/IIB element layer consisting of La₂O₃ and having a thickness of 0.4 nm. In other words, the third gate structure is obtained by annealing the second gate structure. Comparison of the three capacitance density curves (310, 320, 330) show that the third capacitance density curve shows that the third gate structure provides the highest capacitance density in the on-state.

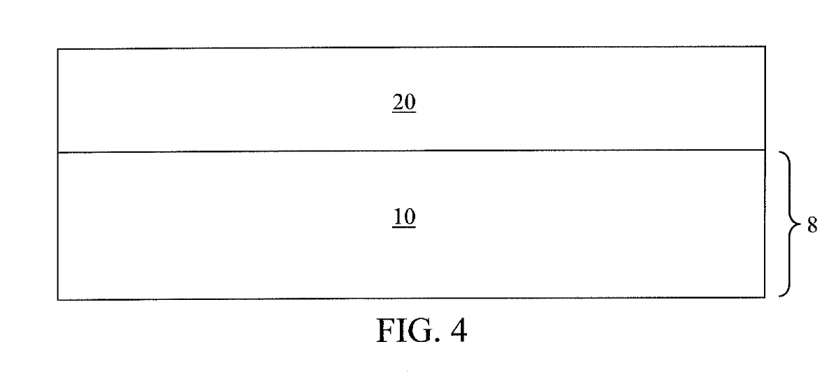

Referring to FIG. 4, a second exemplary semiconductor structure according to a second embodiment of the present invention is derived from the first exemplary semiconductor structure of FIG. 2 by removing the metal aluminum nitride layer 30 and the semiconductor layer 40 by an etch, which may be a dry etch or a wet etch, that is selective to the mixed high-k material layer 20. The semiconductor layer 40 and the metal aluminum nitride layer 30 may be removed sequentially.

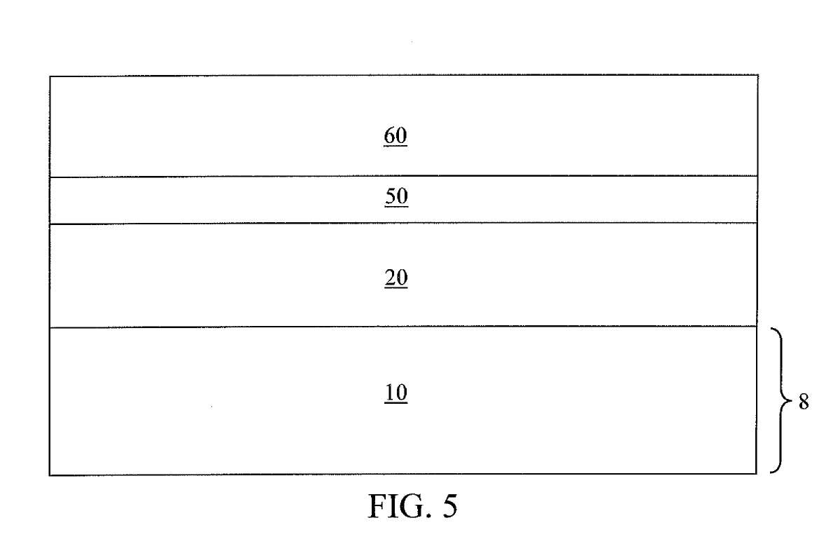

Referring to FIG. 5, a band edge metal layer 50 is formed by depositing a layer of metal that has Fermi level near the valence band edge of the semiconductor region 10 or near the conduction band edge of the semiconductor region 10. In case the semiconductor region 10 comprises silicon, the band edge metal layer 50 comprises a silicon valence band edge metal, i.e., a metal having a Fermi level near the valence band edge of silicon, or a silicon conduction band edge metal, i.e., a metal having a Fermi level near the conduction band edge of silicon. Typically, the Fermi level of a metal is considered to be “near” the valence band edge or a “conduction band edge” if the Fermi level of the metal is within 0.3 V of the valence band edge or the conduction band edge. Typical silicon valence band edge metals include Pt, Rh, Ir, Re and Ru, and typical silicon conduction band edge metals include Hf, Ti, and Zr. The thickness of the band edge metal layer 50 may be from about 5 nm to about 30 nm, although lesser and greater thicknesses are explicitly contemplated herein.

A conductive capping layer 60 is thereafter formed directly on the band edge metal layer 50 by depositing a conductive material. The conductive capping layer 60 may comprise doped polysilicon or one of TaAlN, TiN, ZrN, HfN, VN, NbN, TaN, WN, TiAlN, TaCN, W, Ta, Ti, other conductive refractory metal nitrides, and an alloy thereof. The thickness of the conductive capping layer 60 may be from about 0.1 nm to about 120 nm, and typically from about 10 nm to about 50 nm, although lesser and greater thicknesses are also explicitly contemplated herein.

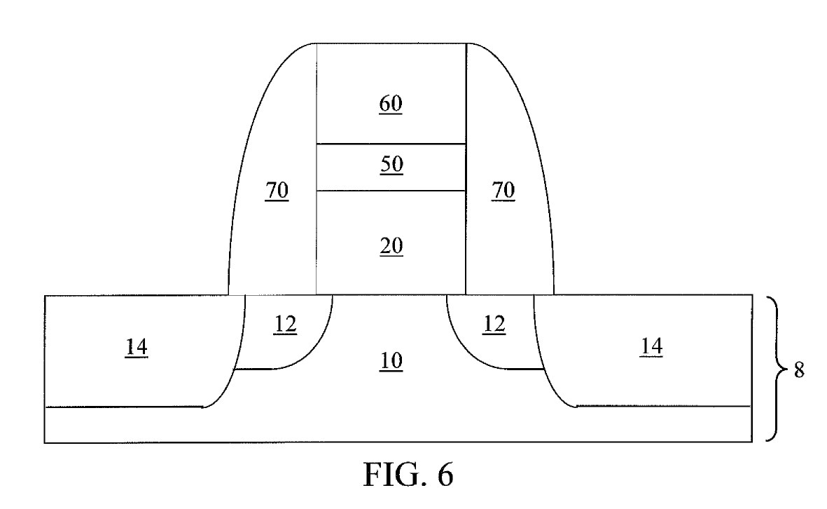

Referring to FIG. 6, the conductive capping layer 60, the band edge metal layer 50, and the mixed high-k material layer 20 are patterned by lithographic methods and a series of anisotropic etches. The remaining portions of the conductive capping layer 60, the band edge metal layer 50, and the mixed high-k material layer 20 collectively constitute a gate stack (20, 50, 60). Source and drain extension regions 12 are formed in the semiconductor substrate 8 by implanting dopants, which may be p-type dopants or n-type dopants. A dielectric spacer 70 is formed by conformal deposition of a dielectric material layer and an anisotropic reactive ion etch (RIE). Source and drain regions 14 are formed by implanting dopants into the portions of the semiconductor substrate 8 that are not covered by the gate stack (20, 50, 60) and the dielectric spacer 70. The gate stack (20, 50, 60) is formed prior to the formation of the source and drain regions 14.

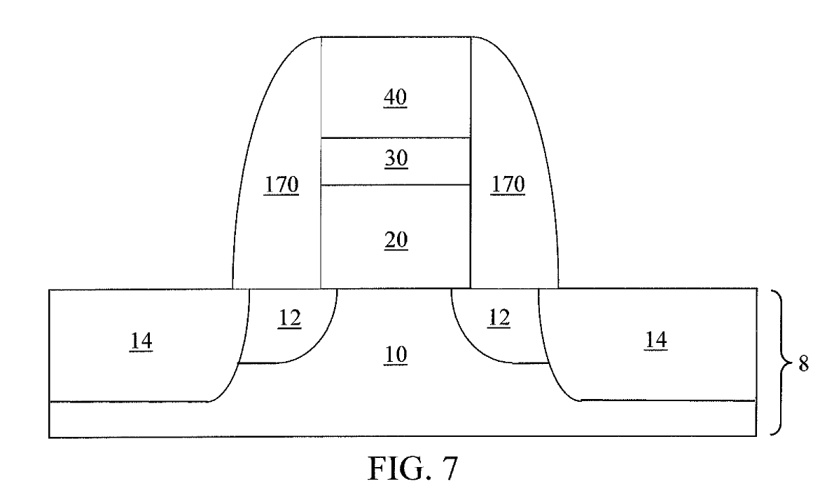

Referring to FIG. 7, a third exemplary semiconductor structure according to a third embodiment of the present invention is derived from the first exemplary semiconductor structure of FIG. 2 by patterning the semiconductor layer 40, the metal aluminum nitride layer 30, and the mixed high-k material layer 20 by lithographic methods and a series of anisotropic etches. The remaining portions of the semiconductor layer 40, the metal aluminum nitride layer 30, and the mixed high-k material layer 20 collectively constitute a dummy gate stack (20, 30, 40). Source and drain extension regions 12 are formed in the semiconductor substrate 8 by implanting dopants into exposed regions of the semiconductor substrate 8. A dielectric spacer 170 is formed by conformal deposition of a dielectric material layer and an anisotropic reactive ion etch VIE). The dielectric spacer 170 comprises a dielectric material such as a dielectric oxide, a dielectric oxynitride, or a dielectric nitride. For example, the dielectric spacer may comprise doped or undoped silicon oxide, silicon oxynitride, or silicon nitride. Source and drain regions 14 are formed by implanting dopants into the portions of the semiconductor substrate 8 that are not covered by the dummy gate stack (20, 30, 40) and the dielectric spacer 170.

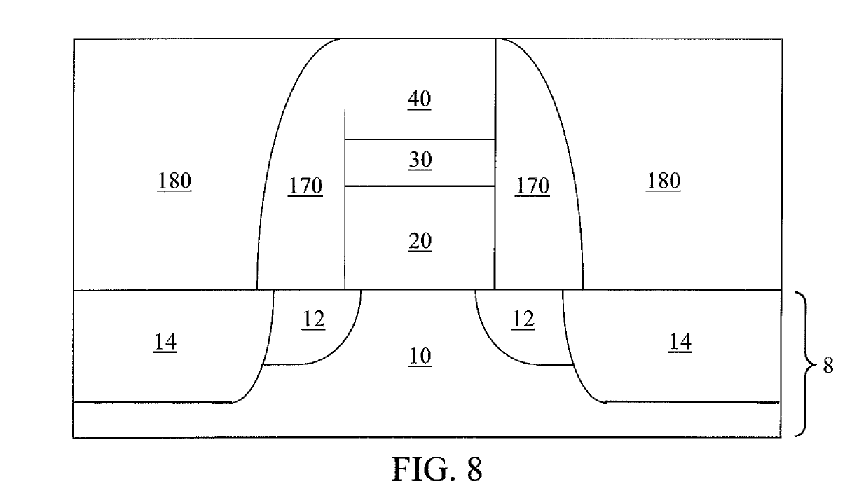

Referring to FIG. 8, a dielectric layer 180 is formed over the dummy gate stack (20, 30, 40) and the dielectric spacer 170. The dielectric layer 180 comprises a dielectric material such as silicon nitride, doped or undoped silicon oxide, or a combination thereof. The dielectric layer 180 may be formed by a self-planarizing method such as application of spin-on glass (SOG). Alternately, the dielectric layer 180 may be formed by a non-self-planarizing method such as chemical vapor deposition of a dielectric material. In this case, the dielectric layer 180 is planarized by chemical mechanical polishing (CMP) to expose the semiconductor layer 40 in the dummy gate stack (20, 30, 40). Recess etch may optionally be employed to facilitate planarization of the dielectric layer 180. After planarization, a top surface of the dielectric layer 180 is substantially coplanar with a top surface of the dummy gate stack (20, 30, 40).

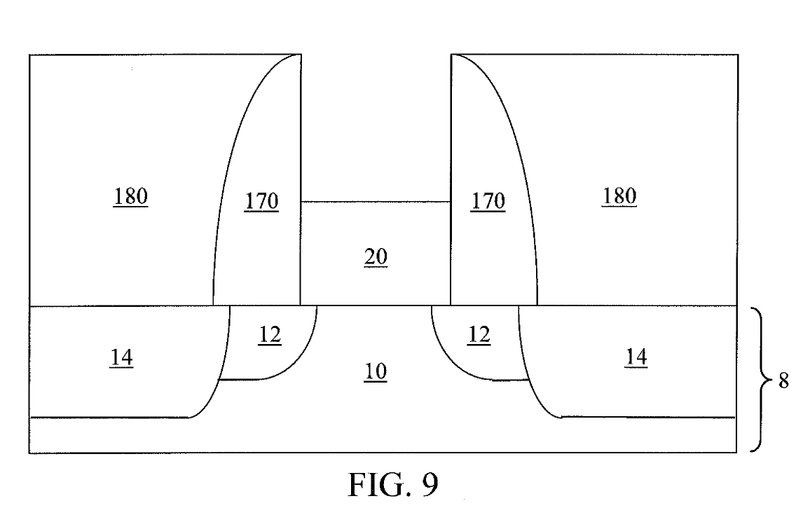

Referring to FIG. 9, the semiconductor layer 40 and the metal aluminum nitride layer 30 are removed by at least one etch that is selective to the dielectric spacer 170 and the dielectric layer 180. The at least one etch may include a dry etch or a wet etch. The at least one etch may be a series of etches that remove the semiconductor layer 40 and the metal aluminum nitride layer 30 sequentially. The removal of the semiconductor layer 40 and the metal aluminum layer 30 forms a cavity above the mixed high-k material layer 20.

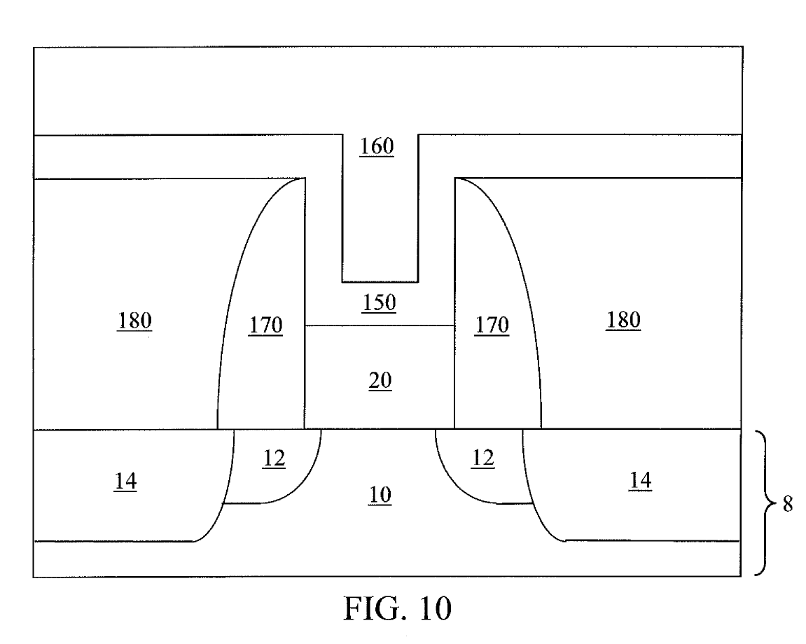

Referring to FIG. 10, the cavity above the mixed high-k material layer is filled with a band edge metal layer 150 and a conductive capping layer 160. The band edge metal layer 150 according to the third embodiment comprises the same material as the band edge metal layer 50 according to the second embodiment described above. The thickness of the band edge metal layer 150 may be from about 5 nm to about 30 nm, although lesser and greater thicknesses are explicitly contemplated herein. The conductive capping layer 160 is thereafter formed directly on the band edge metal layer 150 by depositing a conductive material. The conductive capping layer 160 according to the third embodiment comprises the same material as the conductive capping layer 60 according to the second embodiment described above. The thickness of the conducive capping layer 160 may be from about 10 nm to about 150 nm, and typically from about 30 nm to about 100 nm, although lesser and greater thicknesses are also explicitly contemplated herein.

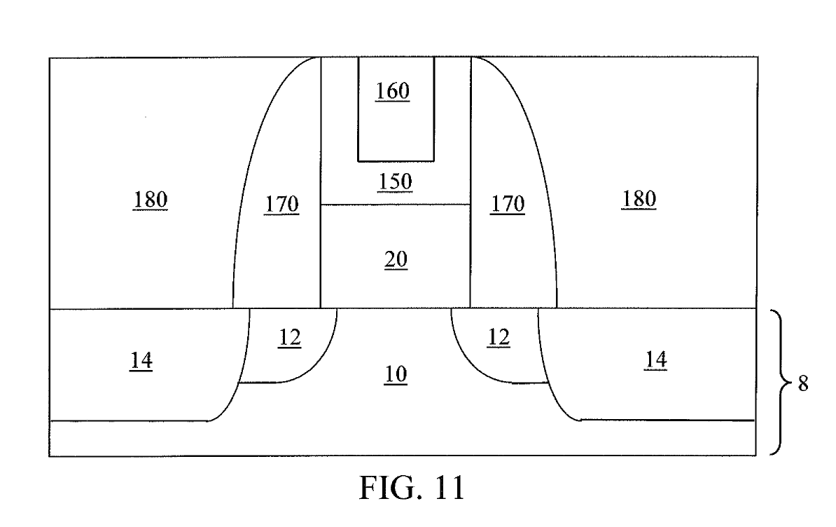

Referring to FIG. 11, the stack of the conductive capping layer 160 and the band edge metal layer 150 are planarized by chemical mechanical planarization (CMP), a recess etch, or a combination thereof. The dielectric layer 180 may be employed as a stopping layer in a CMP process or as an endpoint layer in the recess etch. The top surfaces of the conductive capping layer 160 and the band edge metal layer 150 are substantially planar with a top surface of the dielectric layer 180. The mixed high-k material layer 20, the band edge metal layer 150, and the conductive capping layer 160 collectively constitute a gate stack. In the third embodiment, the gate stack (20, 150, 160) is formed after the formation of the source and drain regions 14.

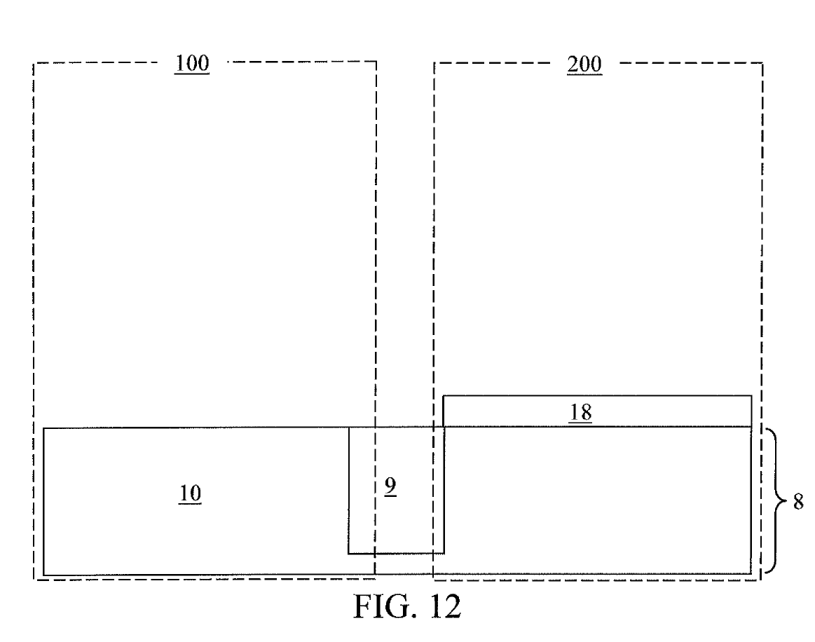

Referring to FIG. 12, a fourth exemplary semiconductor structure according to a fourth embodiment of the present invention comprises a semiconductor substrate 8 containing a semiconductor region 10 and a shallow trench isolation structure 9, which straddles a first device region 100 and a second device region 200 of the semiconductor substrate 8. The shallow trench isolation structure 9 comprises a dielectric material such as silicon oxide and/or silicon nitride, and is formed by methods well known in the art. Preferably, the semiconductor region 10 comprises silicon. A silicon germanium alloy layer 18 is formed on the semiconductor substrate 8 by epitaxy. The silicon germanium alloy layer 18 comprises a silicon germanium alloy having a homogeneous composition or a vertically graded composition. The concentration of germanium in the silicon germanium alloy layer 18 may be from 0% to about 30%, and typically from about 2% to about 15%. The thickness of the silicon germanium alloy layer 18 may be from about 0.3 nm to about 30 nm, and typically from about 1 nm to about 0 nm.

The silicon germanium alloy layer 18 is formed in the second device region 200, while a silicon surface is exposed in the first device region 100. This may be achieved by epitaxially growing a layer of silicon germanium alloy on the entirety of the top surface of the semiconductor substrate 8 and removing the portion of the layer of the silicon germanium alloy in the first device region 100 and above the shallow trench isolation structure 9. Alternatively, a dielectric pad layer (not shown) may be formed directly on the top surface of the semiconductor substrate 8 and patterned to expose the top surface of the semiconductor region in the first device region 100, while covering the second device region 200. A selective epitaxial deposition of a layer of silicon germanium alloy, which forms the silicon germanium alloy layer 18 in the second device region 200, followed by removal of the dielectric pad layer provides the structure of FIG. 12.

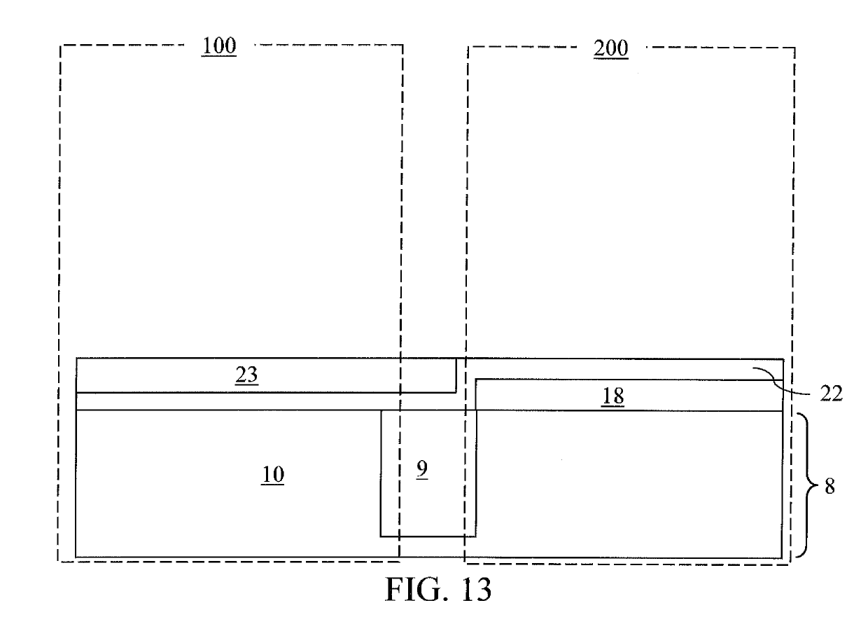

Referring to FIG. 13, a dielectric interface layer 22 is formed directly on the semiconductor region 10 in the first device region and directly on the silicon germanium alloy layer 18 in the second device region 200. The dielectric interface layer 22 in the fourth embodiment comprises the same material and formed by the same method as the dielectric interface layer 22 in the first embodiment. The thickness of the dielectric interface layer 22 may be from about 0.1 nm to about 0.8 nm, although lesser and greater thicknesses are also contemplated herein.

A metal oxide layer 23 is formed directly on the dielectric interface layer 22 by methods well known in the art including, for example, CVD, PVD, MBD, PLD, LSMCD, ALD, etc. The metal oxide layer 23 is thereafter patterned, for example, by lithographic methods and etching, so that the metal oxide layer 23 is removed from the second device region 200, while the metal oxide layer 23 is protected, for example, by a photoresist (not shown), in the first device region 100. The photoresist is thereafter removed.

The metal oxide layer 23 may comprise a high-k material containing a metal and oxygen, known in the art as high-k gate dielectric materials. In this case, the metal oxide layer 23 may comprise one of HfO₂, ZrO₂, La₂O₃, Al₂O₃, TiO₂, SrTiO₃, LaAlO₃, Y₂O₃, HfOₓN_{y}, ZrOₓN_{y}, La₂OₓN_{y}, Al₂OₓN_{y}, TiOₓN_{y}, SrTiOₓN_{y}, LaAlOₓN_{y}, Y₂OₓN_{y}, a silicate thereof, and an alloy thereof. Each value of x is independently from about 0.5 to about 3 and each value of y is independently from 0 to about 2. Non-stoichiometric variants are also contemplated herein. Alternately, the metal oxide layer 23 may comprise an alkaline earth metal-containing oxide. Non-limiting examples of the alkaline earth metal-containing oxide include BeO, MgO, CaO, SrO, BaO, and an alloy thereof. Non-stoichiometric variants are also contemplated herein. The metal oxide layer 23 comprises a different material than the material of a high-k material layer to be subsequently formed thereupon. The thickness of the metal oxide layer 23 may be from about 0.1 nm to about 2 nm, and preferably from about 0.1 nm to about 0.5 nm, although lesser and greater thicknesses are also explicitly contemplated herein.

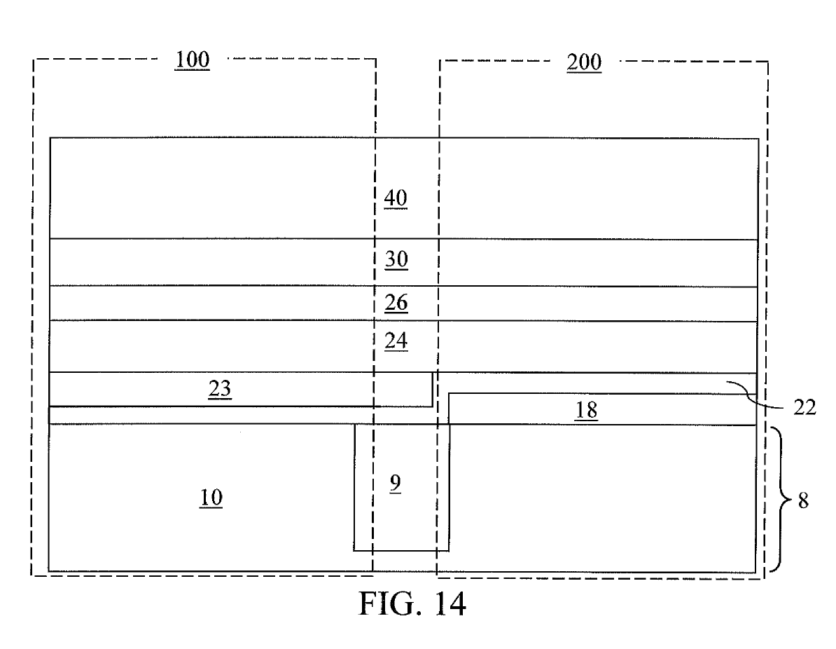

Referring to FIG. 14, a high dielectric constant (high-k) material layer 24 is formed by methods well known in the art. In the first device region 100, the high-k material layer 24 is formed directly on the metal oxide layer 23. In the second device region, the high-k material layer 24 is formed directly on the dielectric interface layer 22. The high-k material layer 24 according to the fourth embodiment comprises the same material as the high-k material layer 24 according to the first embodiment. The high-k material layer 24 comprises a different material than the material of the metal oxide layer 23. The thickness of the high-k material layer 24 may be from about 0.9 nm to about 6 nm, and preferably from about 1.2 nm to about 3 nm. The high-k material layer 24 may have an effective oxide thickness on the order of or less than 1 nm.

A group IIA/IIB element layer 26 is thereafter formed directly on the high-k material layer 24 by methods well known in the art. The group IIA/IIB element layer 26 according to the fourth embodiment comprises the same material as the group IIA/IIB element layer 26 according to the first embodiment. The thickness of the group IIA/IIB element layer 26 may be from about 0.1 nm to about 0.8 nm, although lesser and greater thicknesses are also explicitly contemplated.

A metal aluminum nitride layer 30 is formed directly on the group IIA/IIIB element layer 26 by deposition methods known in the art. The metal aluminum nitride layer 30 according to the fourth embodiment comprises the same material as the metal aluminum nitride layer 30 according to the first embodiment. The thickness of the metal aluminum nitride layer 30 may be from about 0.1 nm to about 100 nm, and typically from about 1 nm to about 10 nm, although lesser and greater thicknesses are also explicitly contemplated herein.

A semiconductor layer 40 is formed directly on the metal aluminum nitride layer 30 by deposition methods well known in the art. The semiconductor layer 40 according to the fourth embodiment comprises the same material as the semiconductor layer 40 according to the first embodiment. The thickness of the semiconductor layer 40 may be from about 11 nm to about 120 nm, although lesser and greater thicknesses are also explicitly contemplated herein.

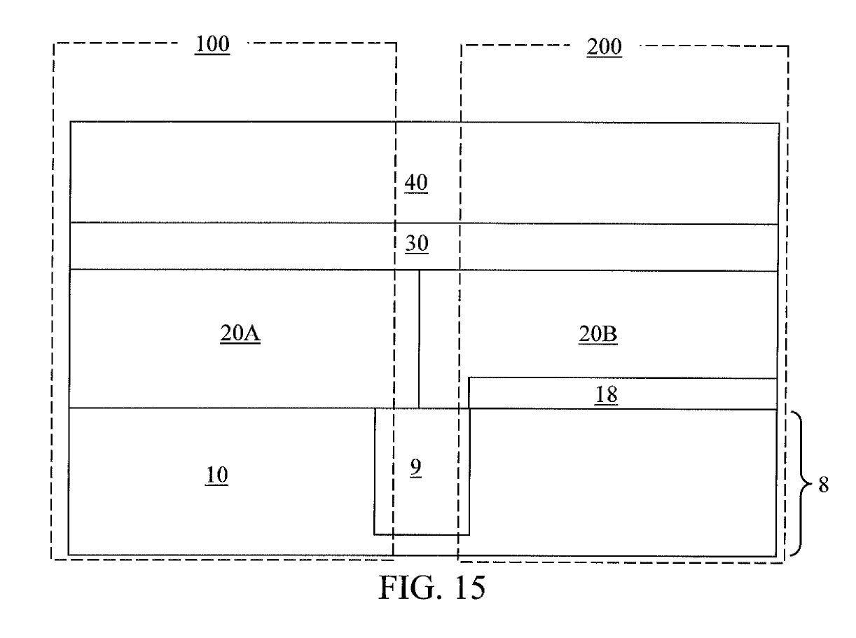

Referring to FIG. 15, the fourth exemplary semiconductor structure is annealed at an elevated temperature to induce interdiffusion of materials in the collective set of the dielectric interface layer 22, the metal oxide layer 23, the high-k material layer 24, and the group IIA/IIB element layer 26. Specifically, the material of the dielectric interface layer 22, the metal oxide layer 23, the high-k material layer 24, and the group IIA/IIB element layer 26 are mixed by interdiffusion to form a first mixed high-k material layer 20A in the first device region 100. The material of the dielectric interface layer 22, the high-k material layer 24, and the group IIA/IIB element layer 26 are mixed by interdiffision to form a second mixed high-k material layer 20B. In addition, some aluminum atoms diffuse out of the metal aluminum nitride layer 30 into the first mixed high-k material layer 20A and into the second mixed high-k material layer 20B.

The mixing herein includes complete homogenization in which each of the first mixed high-k material layer 20A and the second high-k material layer 20B becomes completely homogeneous respectively, as well as substantial homogenization in which each of the first mixed high-k material layer 20A and the second mixed high-k material layer becomes substantially homogeneous. Alternately, each of the first mixed high-k material layer 20A and the second mixed high-k material layer 20B may be vertically graded in composition with a concentration gradient in aluminum or one of the group IIA elements and the group IIIB elements. Thus, each of the first mixed high-k material layer 20A and the second mixed high-k material layer 20B may be a homogenized high-k material layer or a vertically graded high-k material layer.

Due to the presence of the metal oxide layer 23 in the first device region 100 and the absence of the metal oxide layer 23 in the second device region 200, the first mixed high-k material layer 20A and the second mixed high-k material layer 20B have different compositions. The material for the metal oxide layer 23 may be selected to optimize threshold voltages of the devices to be formed employing the first mixed high-k material layer. For example, La₂O₃ or MgO may be employed for the metal oxide layer 23 so that an n-type field effect transistor may have a threshold voltage shifted from a mid-gap value toward the valence band edge of silicon. By selecting the composition and thickness of the metal oxide layer 23, the composition of the first mixed high-k material layer 20A may be optimized to achieve a desired threshold voltage in the devices employing the first mixed high-k material layer 20A.

The anneal conditions employed to form the first and second mixed high-k material layers (20A, 20B) may be substantially the same as the anneal conditions employed in the first embodiment. The first mixed high-k material layer 20A comprises the material of the high-k material layer 24, the metal oxide layer 23, aluminum, and the material of the IIA/IIB element layer 26, which is one of the group IIA elements and the group IIIB elements. In case the metal oxide layer 23 comprises a high-k material containing a metal and oxygen, the first mixed high-k material layer 20A comprises one of the materials listed for the mixed high-k material layer 20 in the first embodiment described above. In case the metal oxide layer 23 comprises an alkaline earth metal-containing oxide, the first mixed high-k material layer 20A may comprise one of HfAₛMₚAl_{q}O₂₊ᵣ, ZrAₛMₚAl_{q}O₂₊ᵣ, La₂AₛMₚAl_{q}O₃₊ᵣ, Al₂AₛMₚO₃₊ᵣ, TiAₛMₚAl_{q}O₂₊ᵣ, SrTiAₛMₚAl_{q}O₃₊ᵣ, LaAlAₛMₚO₃₊ᵣ, Y₂AₛMₚAl_{q}O₃₊ᵣ, HfAₛMₚAl_{q}OₓN_{y}, ZrAₛMₚAl_{q}OₓN_{y}, La₂AₛMₚAl_{q}OₓN_{y}, Al₂AₛMₚOₓN_{y}, TiAₛMₚAl_{q}OₓN_{y}, SrTiAₛMₚAl_{q}OₓN_{y}, LaAlAₛMₚOₓN_{y}, Y₂AₛMₚAl_{q}OₓN_{y}, a silicate thereof, and an alloy thereof. M is selected from the group IIA elements and the group IIIB elements, i.e., Be, Mg, Ca, Sr, Ba, Ra, Sc, Y, La, Ce, Pr, Nd, Pm, Sm, Eu, Gd, Tb, Dy, Ho, Er, Tm, Yb, and Lu. Each value of p is independently from 0 and to about 0.5, and each value of q is independently from 0 and to about 0.5, and each value of r is independently from about 0 and to about 1. A is an alkaline earth material, i.e., one of Be, Mg, Ca, Sr, and Ba. The value of s is from about 0 and to about 1. Each value of x is independently from about 0.5 to about 3, and each value of y is independently from 0 to about 2.

Since the metal oxide layer 23 is not present in the second device region 200 prior to the anneal, the second mixed high-k material layer 20B comprises the same material as the mixed high-k material layer 20 in the first embodiment described above. Since the high-k material layer 24 and the metal oxide layer 23 have different compositions prior to the anneal, the first mixed high-k material layer 20A and the second mixed high-k material layer 23B have different compositions after the anneal. Each of the first and second mixed high-k material layers (20A, 20B) has a high dielectric constant greater than 8.0. The first mixed high-k material layer 20A directly contacts the semiconductor region 10, and the second mixed high-k material layer 20B directly contacts the silicon germanium alloy layer 18. Such direct contacts provide the advantage of higher capacitance density and higher effective dielectric constant, and also enables scaling of a gate dielectric, which consists of the first mixed high-k material layer 20A or the second mixed high-k material layer 20B, and does not contain an interfacial dielectric layer having a dielectric constant less than 8.0 according to the present invention.

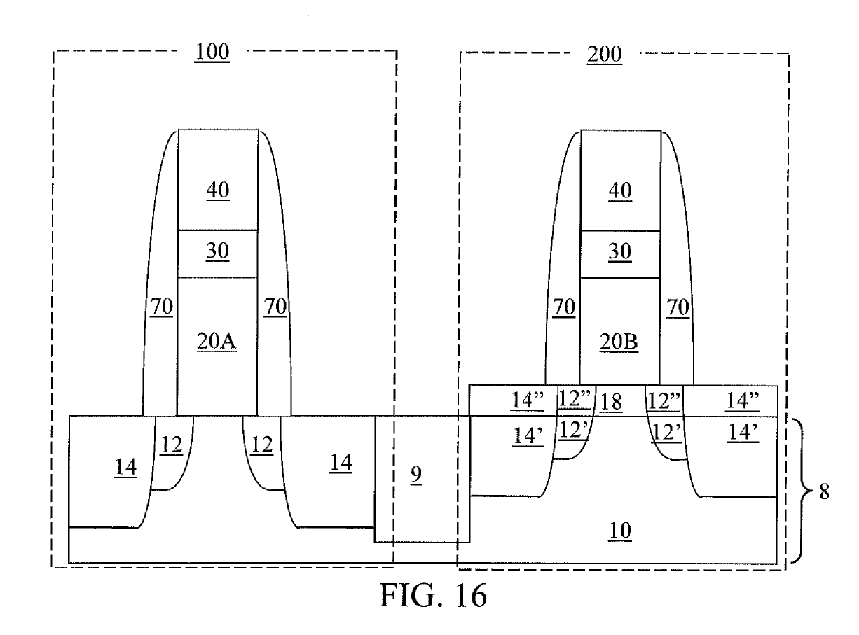

Referring to FIG. 16, the semiconductor layer 40, the metal aluminum nitride layer 30, the first mixed high-k material layer 20A, and the second mixed high-k material layer 2013 are patterned by lithographic methods and a series of anisotropic etches. The remaining portions of the semiconductor layer 40, the metal aluminum nitride layer 30, and the first mixed high-k material layer 20A in the first device region 100 collectively constitute a first gate stack (20A, 30, 40). Likewise, the remaining portions of the semiconductor layer 40, the metal aluminum nitride layer 30, and the second mixed high-k material layer 20B in the second device region 200 collectively constitute a second gate stack (20B, 30, 40).

Source and drain extension regions 12 are formed around the first gate stack (20A, 30, 40) in a portion of the semiconductor substrate 8 in the first device region 100 by implanting dopants, while masking the second device region, for example, with a patterned photoresist (not shown). Likewise, source and drain extension silicon germanium alloy portions 12″ and source and drain extension semiconductor region portions 12′ are formed in the silicon germanium alloy layer 18 and in the semiconductor region 10, respectively. Dielectric spacers 70 are formed by conformal deposition of a dielectric material layer and an anisotropic reactive ion etch (RIE) around the first gate stack (20A, 30, 40) and the second gate stack (20B, 30, 40), respectively. Source and drain regions 14 are formed in a portion of the semiconductor substrate 8 in the first device region 100 by masked ion implantation of dopants. Likewise, source and drain silicon germanium alloy portions 14″, and source and drain semiconductor region portions 14′ are formed in the silicon germanium alloy layer 18 and in the semiconductor region 10, respectively.

The different compositions of the first gate stack (20A, 30, 40) and the second gate stack (20B, 30, 40) as well as the different compositions of the channels, i.e., the region of the semiconductor material directly below the first mixed high-k material layer 20A and the second mixed high-k material layer 20B, may be advantageously employed to optimize threshold voltages of transistors to be formed in the first and second device regions (100, 200). For example, an n-type field effect transistor having a threshold voltage near the valence band edge of the semiconductor material in the semiconductor region 10 may be formed in the first device region 100, while a p-type field effect transistor having a threshold voltage near the conduction band edge of the silicon germanium alloy in the silicon germanium alloy layer 18 may be formed in the second device region 200.

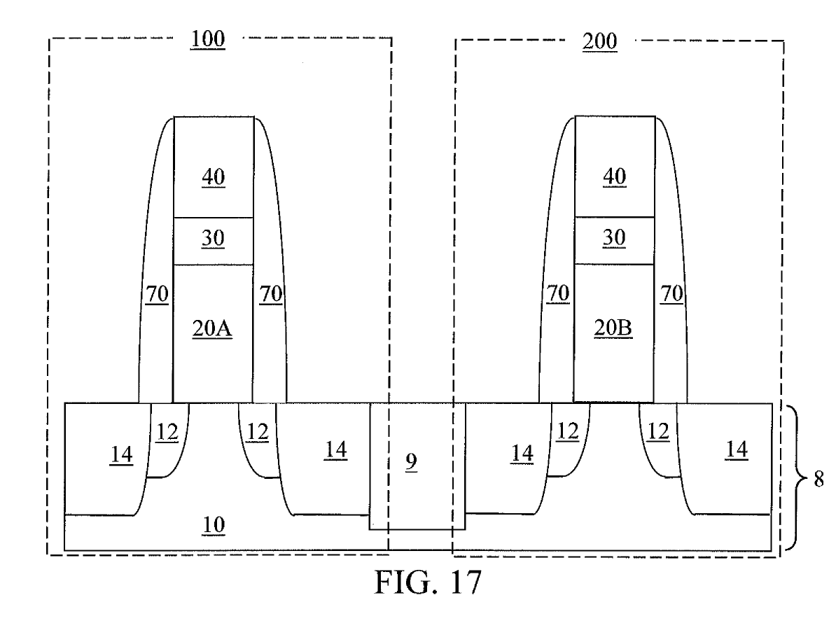

Referring to FIG. 17, a fifth exemplary semiconductor structure according to a fifth embodiment of the present invention may be formed employing the same methods as in the fourth embodiment of the present invention, while eliminating the formation of a silicon germanium alloy layer (See FIG. 12). Thus, the dielectric interface layer 22 is formed directly on the semiconductor region 10 in the first device region 100 and in the second device region 200.

Due to the absence of a silicon germanium layer, source and drain extension ion implantation forms source and drain extension regions 12 in the second device region 200. Likewise, source and drain ion implantation forms source and drain regions 14 in the second device region. It is understood that source and drain extension regions 12 and source and drain regions 14 across the first and second device regions (100, 200) may have a doping of the same or different polarity. For example, an n-type transistor may be formed in the first device region 100, and a p-type transistor may be formed in the second device region 200.

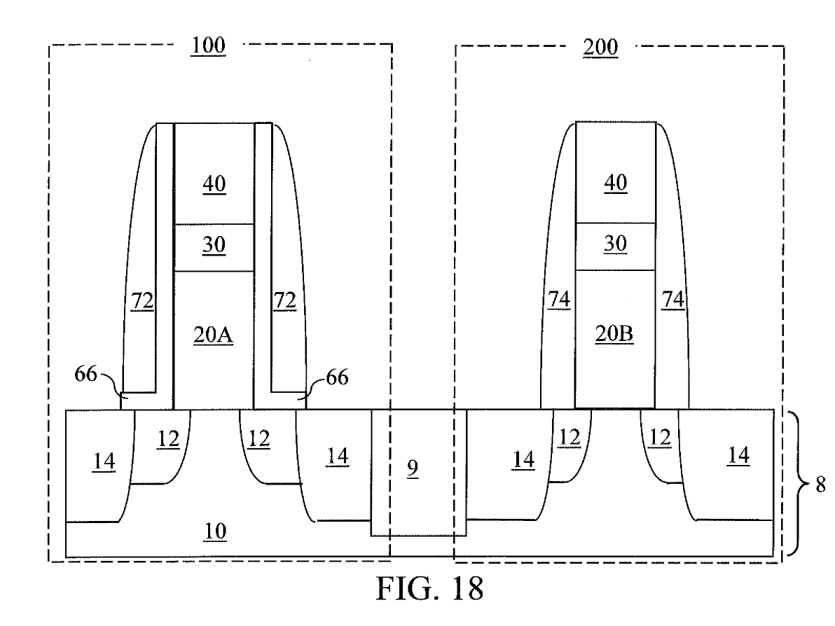

Referring to FIG. 18, a sixth exemplary semiconductor structure according to a sixth embodiment of the present invention is formed by employing methods of the fifth embodiment of the present invention up to the step of formation of the source and drain extension regions 12. A dielectric nitride layer (not shown) is formed by a conformal blanket deposition, for example, by chemical vapor deposition (CVD), and lithographically patterned so that the dielectric nitride layer is present in the first device region 100 and absent in the second device region 200. A dielectric oxide layer (not shown) is formed by a conformal deposition by a blanket deposition. The dielectric oxide layer and the dielectric nitride layer are etched by an anisotropic reactive ion etch so that a dielectric nitride spacer 66 is formed directly on the sidewalls of the first gate stack (20A, 30, 40). A remaining portion of the dielectric oxide layer in the first device region 100 constitutes a first dielectric oxide spacer 72. A remaining portion of the dielectric oxide layer in the second device region 200 constitutes a second dielectric oxide layer 74. The first dielectric oxide spacer 72 and the second dielectric oxide spacer 74 comprise the same material. For example, the dielectric nitride spacer 66 may comprise silicon nitride, and the first dielectric oxide spacer 72 and the second dielectric oxide spacer 74 may comprise silicon oxide.

The sixth exemplary semiconductor structure is annealed in an oxygen ambient to allow diffusion of oxygen into the second mixed high-k material layer 20B, while the dielectric nitride spacer 66 prevents diffusion of oxygen into the first mixed high-k material layer 20A. The temperature of the anneal may be from about 300° C. to about 600° C., and preferably from about 400° C. to about 500° C. The oxygen partial pressure may be from 100 mTorr to about 20 atm, and typically about 1 atm. The duration of the anneal may be from about 10 min to about 6 hours. In general, the duration of the anneal decreases with an increase in the anneal temperature and/or the partial pressure of oxygen.

During the anneal in the oxygen ambient, atomic oxygen and/or oxygen molecules diffuse through the second dielectric oxide 74 and increase oxygen content of the second mixed high-k material layer 20B. In contrast, due to the dielectric nitride spacer 66, the oxygen content of the first mixed high-k material layer 20A remains the same. Thus, the second mixed high-k material layer 20B may have a higher concentration of oxygen than the first mixed high-k material layer 20A. The differences in the oxygen content may advantageously be employed to optimize threshold voltages of transistors formed in the first and second device regions (100, 200) independently.

Variations of the sixth embodiment in which a metal oxide layer is omitted during the formation of the first mixed high-k material layer 20A are explicitly contemplated herein. Variations in which a silicon germanium alloy layer is formed directly underneath the second mixed high-k material layer 20B as in the fourth embodiments are also explicitly contemplated herein.

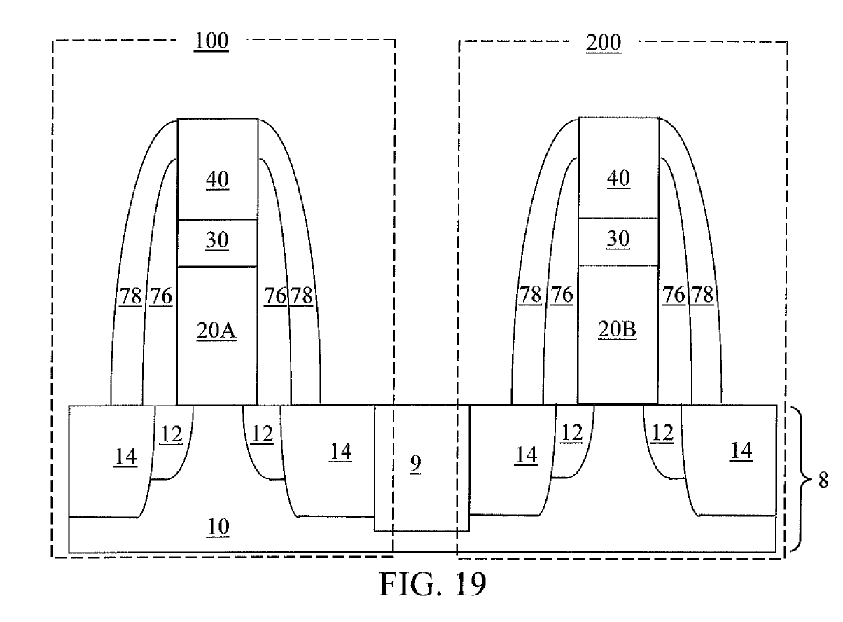

Referring to FIG. 19, a seventh exemplary semiconductor structure according to a seventh embodiment of the present invention is formed by employing methods of the fifth embodiment of the present invention up to the step of formation of the source and drain extension regions 12. First dielectric spacers 76 are formed directly on the sidewalls of the first gate stack (20A, 30, 40) and the second gate stack (20B, 30, 40) by a conformal deposition of a dielectric layer and an anisotropic etch such as a reactive ion etch. The first dielectric spacers 76 comprise a dielectric material such as a dielectric oxide or a dielectric nitride. The first dielectric spacers 76 may comprise an oxygen-permeable material, i.e., a material through which oxygen may diffuse through, such as silicon oxide, or may comprise an oxygen-impermeable material, i.e., a material through which oxygen does not diffuse through, such as silicon nitride.

In case the first dielectric spacers 76 comprise a oxygen-permeable material, an oxygen-impermeable dielectric spacer 78 is formed by deposition of a dielectric material layer comprising an oxygen-impermeable material and an anisotropic etch. For example, the oxygen-impermeable dielectric spacer 78 may comprise silicon nitride. In case the first dielectric spacers 76 comprise an oxygen-impermeable material, an oxygen-impermeable dielectric spacer 78 is optional, i.e., the oxygen-impermeable dielectric spacer 78 may, or may not, be formed.

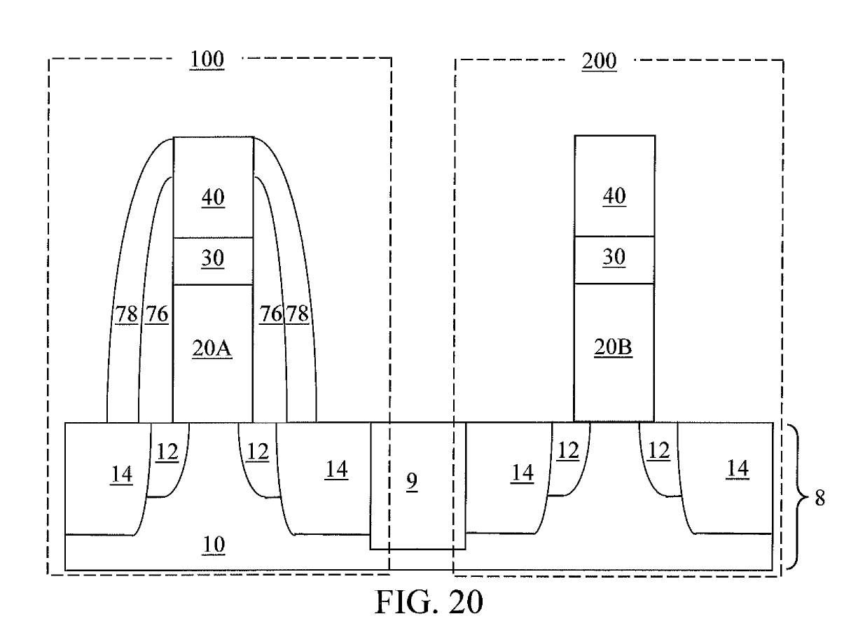

Referring to FIG. 20, the first dielectric spacer 76 and the oxygen-impermeable dielectric spacer 78, if present, in the second device region 200 are removed, for example, by masking the first device region 100 and etching the first dielectric spacer 76 and the oxygen-impermeable dielectric spacer 78, if present, selective to the second mixed high-k material layer 20B and the semiconductor substrate 8. The seventh exemplary semiconductor structure is then annealed in an oxygen ambient to allow diffusion of oxygen into the second mixed high-k material layer 20B, while the first dielectric spacer 76 and/or the oxygen-impermeable dielectric spacer 78, if present, prevent diffusion of oxygen into the first mixed high-k material layer 20A. The same anneal conditions may be employed as in the sixth embodiment of the present invention.

During the anneal in the oxygen ambient, atomic oxygen and/or oxygen molecules diffuse into the second mixed high-k material layer 20B without hindrance and increase oxygen content of the second mixed high-k material layer 20B. In contrast, due to the first dielectric spacer 76 and/or the oxygen-impermeable dielectric spacer 78, if present, the oxygen content of the first mixed high-k material layer 20A remains the same. Thus, the second mixed high-k material layer 20B may have a higher concentration of oxygen than the first mixed high-k material layer 20A. The differences in the oxygen content may advantageously be employed to optimize threshold voltages of transistors formed in the first and second device regions (100, 200) independently.

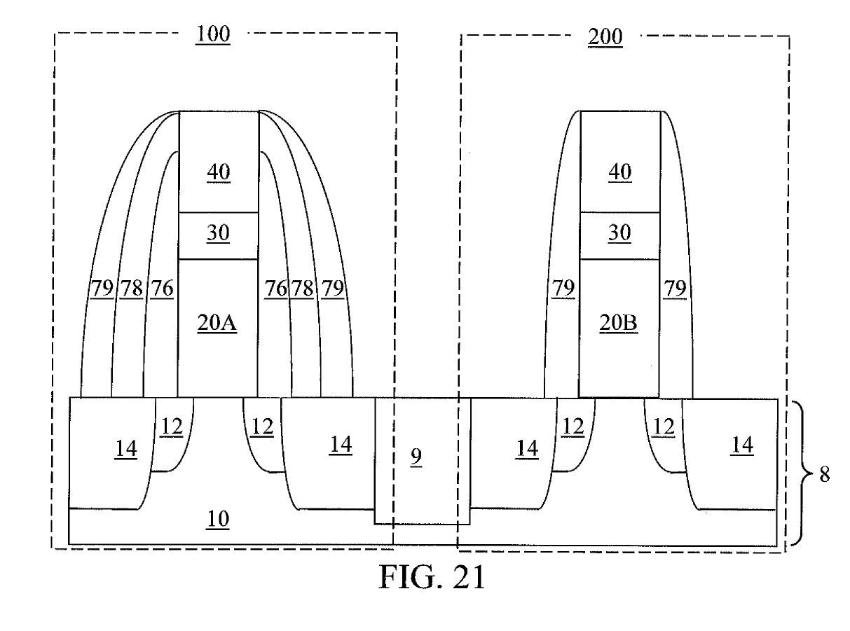

Referring to FIG. 21, second dielectric spacers 79 are formed directly on the first dielectric spacer 76 or the oxygen-impermeable dielectric spacer 78 in the first device region 100 and directly on the sidewalls of the second gate stack (20B, 30, 40) in the second device region 200. The composition of the second dielectric spacers 79 may be the same as, or different from, the composition of the first dielectric spacer 76.

Variations of the seventh embodiment in which a metal oxide layer is omitted during the formation of the first mixed high-k material layer 20A are explicitly contemplated herein. Variations in which a silicon germanium alloy layer is formed directly underneath the second mixed high-k material layer 20B as in the fourth embodiments are also explicitly contemplated herein.

While the invention has been described in terms of specific embodiments, it is evident in view of the foregoing description that numerous alternatives, modifications and variations will be apparent to those skilled in the art. Accordingly, the invention is intended to encompass all such alternatives, modifications and variations which fall within the scope and spirit of the invention and the following claims.

What is claimed is:

1. A semiconductor structure comprising:
a high dielectric constant (high-k) material layer vertically abutting a top surface of a semiconductor substrate and comprising a dielectric material having a dielectric constant greater than 8.0 and doped with aluminum and a group IIA element or a group IIIB element; and
a metallic layer located directly on said high-k material layer.

2. The semiconductor structure of claim 1, wherein said high-k material layer is homogeneous or vertically graded in composition with a concentration gradient in aluminum or one of the group IIA elements and the group IIIB elements.

3. The semiconductor structure of claim 1, wherein said high-k material layer comprises one of HfMₚAl_{q}O₂₊ᵣ, ZrMₚAl_{q}O₂₊ᵣ, La₂MₚAl_{q}O₃₊ᵣ, Al₂MₚO₃₊ᵣ, TiMₚAl_{q}O₂₊ᵣ, SrTiMₚAl_{q}OₓN_{y}, LaAlMₚOₓN_{y}, Y₂MₚAl_{q}O₃₊ᵣ, HfMₚAl_{q}OₓN_{y}, ZrMₚAl_{q}OₓN_{y}, La₂MₚAl_{q}OₓN_{y}, Al₂OₓN_{y}, TiMₚAl_{q}OₓN_{y}, SrTiMₚAl_{q}OₓN_{y}, LaAlMₚOₓN_{y}, Y₂MₚAl_{q}OₓN_{y}, a silicate thereof, and an alloy thereof, wherein M is selected from Be, Mg, Ca, Sr, Ba, Ra, Sc, Y, La, Ce, Pr, Nd, Pm, Sm, Eu, Gd, Tb, Dy, Ho, Er, Tm, Yb, and Lu, and wherein each value of p is independently from 0 and to about 0.5, and each value of q is independently from 0 and to about 0.5, and each value of r is independently from about 0 and to about 1, and each value of x is independently from about 0.5 to about 3, and each value of y is independently from 0 to about 2.

4. The semiconductor structure of claim 1, wherein said metallic layer comprises a metal aluminum nitride containing aluminum, nitrogen, and a metal other than aluminum.

5. The semiconductor structure of claim 2, further comprising a semiconductor layer abutting said metal aluminum nitride layer.

6. The semiconductor structure of claim 1, said metallic layer comprises a silicon valence band edge metal or a silicon conduction band edge metal, wherein said silicon valence band edge metal is one of Pt, Rh, Ir, and Ru, Re and wherein said silicon conduction band edge metal is one of Hf, Ti, and Zr.

7. The semiconductor structure of claim 6, further comprising a conductive capping layer abutting said metallic layer, wherein said conductive capping layer comprises doped polysilicon or one of TaAlN, TiN, ZrN, HfN, VN, NbN, TaN, WN, TiAlN, TaCN, W, Ta, Ti, other conductive refractory metal nitrides, and an alloy thereof.

8. A semiconductor structure comprising:
a first high dielectric constant (high-k) material layer vertically abutting a top surface of a semiconductor substrate and comprising a first dielectric material having a dielectric constant greater than 8.0 and doped with aluminum and a group IIA element or a group IIIB element;
a first metallic layer located directly on said first high-k material layer;
a second high dielectric constant (high-k) material layer located on said semiconductor substrate, disjoined from said first high-k material layer, and comprising a second dielectric material having a dielectric constant greater than 8.0 and doped with aluminum and a group IIA element or a group IIIB element, wherein said first dielectric material and said second dielectric material have different compositions; and
a second metallic layer located directly on said second high-k material layer;

9. The semiconductor structure of claim 8, wherein each of said first high-k material layer and said second high-k material layer comprises one of HfMₚAl_{q}O₂₊ᵣ, ZrMₚAl_{q}O₂₊ᵣ, La₂MₚAl_{q}O₃₊ᵣ, Al₂MₚO₃₊ᵣ, TiMₚAl_{q}O₂₊ᵣ, SrTiMₚAl_{q}O₃₊ᵣ, LaAlMₚO₃₊ᵣ, Y₂MₚAl_{q}O₃₊ᵣ, HfMₚAl_{q}OₓN_{y}, ZrMₚAl_{q}OₓN_{y}, La₂MₚAl_{q}OₓN_{y}, Al₂MₚOₓN_{y}, TiMₚAl_{q}OₓN_{y}, SrTiMₚAl_{q}OₓN_{y}, LaAlMₚOₓN_{y}, Y₂MₚAl_{q}OₓN_{y}, a silicate thereof; and an alloy thereof, wherein M is selected from Be, Mg, Ca, Sr, Ba, Ra, Sc, Y, La, Ce, Pr, Nd, Pm, Sm, Eu, Gd, Tb, Dy, Ho, Er, Tm, Yb, and Lu, and wherein each value of p is independently from 0 and to about 0.5, and each value of q is independently from 0 and to about 0.5, and each value of r is independently from about 0 and to about 1, and each value of x is independently from about 0.5 to about 3, and each value of y is independently from 0 to about 2.

10. The semiconductor structure of claim 8, wherein said first metallic layer and said second metallic layer have the same composition and comprise a metal aluminum nitride containing aluminum, nitrogen, and a metal other than aluminum.

11. The semiconductor structure of claim 8, further comprising a first doped semiconductor layer and a second doped semiconductor layer, wherein said first doped semiconductor layer abuts said first metal layer and said second doped semiconductor layer abuts said second metal layer.

12. The semiconductor structure of claim 8, said first metallic layer comprises a silicon valence band edge metal and said second metallic layer comprises a silicon conduction band edge metal, wherein said silicon valence band edge metal is one of Pt, Rh, Ir, Re, and Ru, and wherein said silicon conduction band edge metal is one of HE, Ti, and Zr.

13. The semiconductor structure of claim 8, further comprising a silicon germanium alloy layer vertically abutting said semiconductor substrate and said second high-k material layer and disjoined from said first high-k material layer.

14. The semiconductor structure of claim 8, further comprising:
a dielectric nitride spacer laterally abutting said first high-k material layer and said first metallic layer;
a first dielectric oxide spacer laterally abutting said dielectric nitride spacer; and
a second dielectric oxide spacer laterally abutting said second high-k material layer and said second metallic layer, wherein said first dielectric oxide spacer and said second dielectric oxide spacer have the same composition.

15. The semiconductor structure of claim 14, wherein said second high-k material layer has a higher atomic percentage of oxygen than said first high-k material layer.

16. The semiconductor structure of claim 8, further comprising:
a first dielectric spacer laterally abutting said first high-k material layer and said first metallic layer; and
a second dielectric spacer laterally abutting said second high-k material layer and said second metallic layer, wherein said first dielectric spacer and said second dielectric spacer have a different composition.

17. A semiconductor structure comprising:
a dielectric interface layer vertically abutting a top surface of a semiconductor substrate, wherein said dielectric interface layer comprises a semiconductor oxide, a semiconductor oxynitride, or a semiconductor nitride;
a high dielectric constant (high-k) material layer vertically abutting said dielectric interface layer, wherein said high-k material layer has a dielectric constant greater than 8.0; and
a group IIA/IIIB element layer vertically abutting said high-k material layer and comprising a group IIA element or a group IIIB element.

18. The semiconductor structure of claim 17, further including a metal aluminum nitride layer vertically abutting said group IIA/IIIB element layer and comprising aluminum, nitrogen, and a metal other than aluminum.

19. A method of manufacturing a semiconductor structure comprising:
forming a stack comprising, from bottom to top, a dielectric interface layer, a high dielectric constant high-k) material layer, and a group III element layer in that order directly on a semiconductor substrate, wherein said dielectric interface layer comprises a semiconductor oxide, a semiconductor oxynitride, or a semiconductor nitride, wherein said high-k material layer has a dielectric constant greater than 8.0, and wherein said group IIA/IIIB element layer comprises one of the group IIA elements and the group IIIB elements;
forming a metal aluminum nitride layer comprising aluminum, nitrogen, and a metal other than aluminum directly on said stack; and
annealing said stack to form a mixed high-k material layer abutting said semiconductor substrate and said metal aluminum nitride layer, wherein said mixed high-k material layer has a dielectric constant greater than 8.0 and comprises aluminum and said one of said group IIA elements and said group IIIB elements.

20. The method of claim 19, further comprising patterning said mixed high-k material layer and said metal aluminum nitride layer to form a gate conductor stack.

21. The method of claim 20, further comprising:
forming a dielectric layer on said gate conductor stack;
planarizing said dielectric layer to expose said gate conductor stack;
removing said metal aluminum nitride layer from said gate conductor stack; and
forming a metallic layer comprising a silicon valence band edge metal or a silicon conduction band edge metal, wherein said silicon valence band edge metal is one of Pt, Rh, Ir, Re and Ru, and wherein said silicon conduction band edge metal is one of Hf. Ti, and Zr.

22. A method of manufacturing a semiconductor structure comprising:
forming a first stack comprising, from bottom to top, a dielectric interface layer, a metal oxide layer, a high dielectric constant (high-k) material layer, and a group IIA/IIIB element layer directly on a first portion of a semiconductor substrate, wherein said dielectric interface layer comprises a semiconductor oxide, a semiconductor oxynitride, or a semiconductor nitride, wherein said high-k material layer has a dielectric constant greater than 8.0, and wherein said a group IIA/IIIB element layer comprises one of the group IIA elements and the group IIIB elements;
forming a second stack comprising, from bottom to top, said dielectric interface layer, said high-k material layer, and said group IIIB element layer directly on a second portion of said semiconductor substrate;
forming a metal aluminum nitride layer comprising aluminum, nitrogen, and a metal other than aluminum directly on said first stack and said second stack; and
annealing said first stack and said second stack to form a first mixed high-k material layer and a second mixed high-k material layer respectively, wherein each of said first mixed high-k material layer and said second mixed high-k material layer abuts said semiconductor substrate and said metal aluminum nitride layer, has a dielectric constant greater than 8.0, and comprises aluminum and said one of said group IIA elements and said group IIIB elements, and wherein said first mixed high-k material layer and said second mixed high-k material layer have different compositions.

23. The method of claim 22, her comprising forming a silicon germanium alloy layer directly on a portion of said semiconductor substrate, wherein said second high-k material layer is formed directly on said portion of said semiconductor substrate, wherein said first high-k material layer is formed directly on said semiconductor substrate, and wherein said semiconductor substrate comprises silicon.

24. The method of claim 22, further comprising:
forming a dielectric nitride spacer directly on said first mixed high-k material layer and said first metallic layer;
forming a first dielectric oxide spacer directly on said dielectric nitride spacer; and
forming a second dielectric oxide spacer directly on said second high-k material layer and said second metallic layer, wherein said first dielectric oxide spacer and said second dielectric oxide spacer have the same composition.

25. The method of claim 22, further comprising:
forming a first dielectric spacer on said semiconductor substrate, wherein a first portion of said first dielectric layer laterally abuts said first mixed high-k material layer and a second portion of said first dielectric layer laterally abuts said second mixed high-k material layer;
removing said second portion to expose sidewalls of said second mixed high-k material layer, while preserving said first portion; and
oxidizing said second mixed high-k material layer, while preventing diffusion of oxygen into said first mixed high-k material layer.
